(19) United States
(12) Patent Application Publication
(10) Pub. No.: US 2025/0324510 A1
(43) Pub. Date: Oct. 16, 2025

(54) CIRCUIT BOARD AND SEMICONDUCTOR PACKAGE COMPRISING SAME

(71) Applicant: LG INNOTEK CO., LTD., Seoul (KR)

(72) Inventors: Sang Il KIM, Seoul (KR); Se Woong NA, Seoul (KR); Kee Han LEE, Seoul (KR)

(21) Appl. No.: 18/692,985

(22) PCT Filed: Sep. 14, 2022
(86) PCT No.: PCT/KR2022/013722

§ 371 Date: Aug. 22, 2024

(30) Foreign Application Priority Data
Sep. 16, 2021 (KR) 10-2021-0124366

(51) Int. Cl. H05K 1/11; H01L 23/00; H01L 23/498; H01L 23/538; H01L 25/065; H01L 25/10; H01L 25/18; H05K 1/18; H10B 80/00; H10D 80/30

(52) U.S. Cl. CPC H05K 1/111; H01L 23/49838; H01L 23/5386; H01L 25/0655; H01L 25/105; H01L 25/18; H05K 1/181; H01L 24/16; H01L 2224/16227; H01L 2924/1532; H05K 2201/0939; H05K 2201/09881; H05K 2201/10159; H05K 2201/10212; H10B 80/00; H10D 80/30

(57) ABSTRACT

A circuit board according to an embodiment includes an insulating layer; a pad disposed on the insulating layer; and a protective layer disposed on the insulating layer and including a recess portion vertically overlapping with the pad, wherein the protective layer includes a first portion including a first part of the recess portion; and a second portion disposed on the first portion and including a second part of the recess portion connected to the first portion, and wherein a width of the second part of the recess portion is greater than a width of the first part of the recess portion.

### TECHNICAL FIELD

The embodiment relates to a circuit board and a semiconductor package including the same.

### BACKGROUND ART

As miniaturization, weight reduction, and integration of an electronic component are accelerated, a line width of a circuit has been miniaturized. In particular, as a design rule of a semiconductor chip is integrated on a nanometer scale, a circuit line width of a package substrate or a printed circuit board on which the semiconductor chip is mounted has been miniaturized to several micrometers or less.

Various methods have been proposed in order to increase a degree of circuit integration of the printed circuit board, that is, to reduce the circuit line width. For the purpose of preventing loss of the circuit line width in an etching step for forming a pattern after copper plating, a semi-additive process (SAP) method and a modified semi-additive process (MSAP) have been proposed.

Then, an embedded trace substrate (hereinafter referred to as “ETS”) method for embedding a copper foil in an insulating layer in order to implement a fine circuit pattern has been used in the industry. In the ETS method, a copper foil circuit is manufactured in an embedded form in the insulating layer instead of forming a copper foil circuit on a surface of the insulating layer, and thus there is no circuit loss due to etching and it is advantageous for miniaturizing a circuit pitch.

Meanwhile, a circuit board as described above has chips mounted on it or is combined with the main board of an external device to form a package substrate.

For this purpose, a recess portion is provided in a protective layer of the circuit board, and solder balls for mounting the chip or coupling to the main board are disposed in the recess portion. Additionally, the package substrate may be manufactured by mounting a chip or coupling a main board on the solder ball and then forming a molding layer for molding it.

However, according to the prior art, the solder ball is placed on the circuit board, and accordingly, a metal contact layer (IMC: Inter Metallic Contact) is formed between the solder ball and a metal layer connected to the solder ball. At this time, when injecting a molding material for forming the molding layer in the manufacturing process of the package substrate, there is a problem that damage caused by the molding material injection pressure is transmitted to the metal contact layer (IMC), resulting in cracks occurring in the metal contact layer (IMC). And, if a crack occurs in the metal bonding layer (IMC), the metal contact layer (IMC) is separated, which causes a reliability problem in which the chip or the main board is separated from the circuit board.

Accordingly, there is a need for a structure that can minimize damage transmitted to the metal contact layer (IMC) due to the injection pressure of the molding material.

### DISCLOSURE

### Technical Problem

An embodiment provides a circuit board with a new structure and a semiconductor package including the same.

Additionally, the embodiment provides a circuit board that can improve the reliability of a metal contact layer (IMC) and a semiconductor package including the same.

Additionally, the embodiment provides a circuit board including a protective layer having a recess portion of a stepped structure and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer; a pad disposed on the insulating layer; and a protective layer disposed on the insulating layer and including a recess portion vertically overlapping with the pad, wherein the protective layer includes a first portion including a first part of the recess portion; and a second portion disposed on the first portion and including a second part of the recess portion connected to the first portion, and wherein a width of the second part of the recess portion is greater than a width of the first part of the recess portion.

In addition, the recess portion includes at least one point among a point where a width changes, a point where an inclination of an inner wall changes, and a point where a curvature of the inner wall changes, and wherein the first part and the second part of the recess portion are divided based on the point.

In addition, the circuit board further comprises a surface treatment layer disposed in the first part of the recess portion.

In addition, an upper surface of the surface treatment layer is located lower than an upper surface of the first portion of the protective layer.

In addition, the circuit board further comprises a solder disposed on the surface treatment layer and disposed in the first part and the second part of the recess portion.

In addition, the first part of the recess portion has a width smaller than a width of the pad.

In addition, the second part of the recess portion has a width greater than the width of the pad.

In addition, the pad includes a first pad and a second pad disposed adjacent to each other on the insulating layer, wherein the recess portion includes a first recess portion vertically overlapping the first pad, and a second recess portion vertically overlapping the second pad, and wherein a spacing between the second part of the first recess portion and the second part of the second recess portion is smaller than a spacing between the first pad and the second pad.

In addition, the first part of the recess portion has a width greater than a width of the pad, wherein at least a portion of a side surface of the pad is spaced apart from the first portion of the protective layer, and he surface treatment layer includes a region in contact with the side surface of the pad.

In addition, a lower surface of the first part of the recess portion is located higher than a lower surface of the pad, and the side surface of the pad includes a first side surface covered by the first portion of the protective layer and a second side surface covered with the surface treatment layer.

In addition, the first part of the recess portion has a width equal to the width of the pad, and the surface treatment layer has a width equal to the width of the pad and is disposed in the first part of the recess portion.

In addition, at least one of the first part and the second part of the recess portion has an inclination whose width gradually decreases toward the pad.

Meanwhile, a circuit board according to another embodiment comprises a first outermost insulating layer; a first outermost circuit pattern layer disposed on the first outermost insulating layer and including a first pad; a first protective layer disposed on the first outermost insulating layer and including a first recess portion vertically overlapping the first pad; a second outermost insulating layer disposed under the first outermost insulating layer; a second outermost circuit pattern layer disposed under the second outermost insulating layer and including a second pad; and a second protective layer disposed under the second outermost insulating layer and including a second recess portion vertically overlapping with the second pad, wherein the first recess portion includes a first-first part having a width smaller than a width of the first pad and formed on the first pad; and a first-second part formed on the first-first part and having a width greater than a width of each of the first pad and the first-first part, and wherein the second recess portion includes a second-first part formed under the second pad and having a width less than a width of the second pad; and a second-second part formed on the second-first part and having a width greater than the width of each of the second pad and the second-first part.

In addition, the circuit board further comprises a first surface treatment layer disposed in the first-first part of the first recess portion and having an upper surface lower than an uppermost end of an inner wall of the first-first part; and a second surface treatment layer disposed in the second-first part of the second recess portion and having a lower surface higher than a lowermost end of an inner wall of the second-first part.

Meanwhile, a package substrate according to the embodiment comprises a first outermost insulating layer; a first outermost circuit pattern layer disposed on the first outermost insulating layer and including a first pad; a first protective layer disposed on the first outermost insulating layer and including a first recess portion that vertically overlaps the first pad and has a first step; a second outermost insulating layer disposed under the first outermost insulating layer; a second outermost circuit pattern layer disposed under the second outermost insulating layer and including a second pad; and a second protective layer disposed under the second outermost insulating layer and including a second recess portion that vertically overlaps the second pad and has a second step; a first surface treatment layer disposed within the first recess portion of the first protective layer and having an upper surface positioned lower than the first step; a first connection part disposed on the first surface treatment layer to fill the first recess portion; a second surface treatment layer disposed within the second recess portion of the second protective layer and having a lower surface positioned higher than the second step; a second connection part disposed under the second surface treatment layer and filling the second recess portion; a chip mounted on the first connection part; and an external board attached under the second connection part.

In addition, the package substrate further comprises a first metal contact layer disposed between an upper surface of the first surface treatment layer and the first connection part; and a second metal contact layer disposed between a lower surface of the second surface treatment layer and the second connection part, wherein an upper surface of the first metal contact layer is located lower than the first step, and a lower surface of the second metal contact layer is positioned higher than the second step.

### Advantageous Effects

The circuit board in the embodiment comprises a protective layer disposed on an outermost layer and having a recess portion that vertically overlaps the pad. At this time, the recess portion formed in the protective layer may have a step. For example, the recess portion formed in the protective layer includes a first part of the recess portion adjacent to the pad and having a first width, and a second part formed on the first part and having a width greater than that of the first part. Accordingly, the embodiment increases a length of an inner wall of the protective layer, thereby increasing a length of an inner wall of the recess portion between an upper surface of the protective layer and the pad. Meanwhile, a surface treatment layer is disposed on the pad, and a solder is disposed on the surface treatment layer. At this time, a metal contact layer is formed between the solder and the surface treatment layer as the solder is disposed on the surface treatment layer. At this time, the embodiment allows the recess portion to have a step, and allows to increase the length of the inner wall of the recess portion between the upper surface of the protective layer and the metal bonding layer while increasing a contact area of an upper surface of the solder.

For example, the comparative example had a structure in which an inflection portion was not provided on the inner wall of the recess portion connecting the upper surface of the protective layer and the metal contact layer (IMC). Accordingly, in the comparative example, a thickness of the protective layer had to be increased in order to increase the distance of the inner wall of the recess portion between the upper surface of the protective layer and the metal contact layer (IMC).

Alternatively, the embodiment may form a step in the recess portion to increase the length of the inner wall of the recess portion between the metal contact layer (IMC) and the upper surface of the protective layer without increasing the thickness of the protective layer, and accordingly, the physical reliability of the metal contact layer (IMC) can be improved.

For example, the inner wall of the recess portion in the embodiment includes a first inner wall corresponding to the first part of the recess portion, a second inner wall corresponding to the second part, and a third inner wall between the first inner wall 161W and the second inner wall. At this time, when a thickness of the protective layer, a thickness of the circuit pattern layer, and a thickness of the surface treatment layer in the comparative example is the same as a thickness of the protective layer, a thickness of the circuit pattern layer, and a thickness of the surface treatment layer in the present embodiment, an inner wall of the recess portion between the upper surface of the protective layer in the comparative example and the surface treatment layer only the first inner wall and the second inner wall. Alternatively, the embodiment allows a third inner wall to be additionally formed between the first inner wall and the second inner wall by providing a step in the recess portion, and a distance between the upper surface of the protective layer and the metal contact layer (IMC) may be increased by a length (or width) of the third inner wall.

Through this, the embodiment can increase the distance between the protective layer and the metal contact layer without increasing the thickness of the protective layer and the circuit board, and thereby stably protect the metal contact layer from various factors. Accordingly, the embodiment can increase the bonding strength between the solder disposed on the surface treatment layer and the circuit pattern layer, and thus improve physical reliability.

Additionally, the embodiment allows the width of the second part of the recess portion to be larger than the width of the pad. Accordingly, the embodiment increases the width of the second part of the recess portion to the maximum within a possible range to further improve the reliability of the metal contact layer (IMC).

### DESCRIPTION OF DRAWINGS

FIG. 1A is a diagram showing a circuit board according to a comparative example.

FIG. 1B is a diagram for explaining the reliability problem of a metal contact layer (IMC) in a comparative example of FIG. 1A.

FIG. 2A is a cross-sectional view showing a semiconductor package according to the first embodiment.

FIG. 2B is a cross-sectional view showing a semiconductor package according to a second embodiment.

FIG. 2C is a cross-sectional view showing a semiconductor package according to a third embodiment.

FIG. 2D is a cross-sectional view showing a semiconductor package according to a fourth embodiment.

FIG. 2E is a cross-sectional view showing a semiconductor package according to a fifth embodiment.

FIG. 2F is a cross-sectional view showing a semiconductor package according to the sixth embodiment.

FIG. 2G is a cross-sectional view showing a semiconductor package according to a seventh embodiment.

FIG. 3 is a diagram showing a circuit board according to the first embodiment.

FIG. 4 is an enlarged view of one region of the circuit board of FIG. 3.

FIG. 5 is a diagram for explaining the reliability of a metal contact layer according to a first embodiment.

FIG. 6 is a diagram showing a first modified example of the circuit board of FIG. 3.

FIG. 7 is a diagram showing a second modified example of the circuit board of FIG. 3.

FIG. 8 is a diagram showing a third modified example of the circuit board of FIG. 3.

FIG. 9 is a diagram showing a circuit board according to a second embodiment.

FIG. 10 is a diagram showing a circuit board according to a third embodiment.

FIG. 11 is a diagram showing a circuit board according to a fourth embodiment.

FIG. 12 is a diagram showing a package substrate according to an embodiment.

FIGS. 13 to 19 are diagrams showing a method of manufacturing a circuit board according to an embodiment in order of processes.

### MODES OF THE INVENTION

Hereinafter, the embodiment disclosed in the present specification will be described in detail with reference to the accompanying drawings, but the same or similar components are designated by the same reference numerals regardless of drawing numbers, and repeated description thereof will be omitted. The component suffixes “module” and “part” used in the following description are given or mixed together only considering the ease of creating the specification, and have no meanings or roles that are distinguished from each other by themselves. In addition, in describing the embodiments disclosed in the present specification, when it is determined that detailed descriptions of a related well-known art unnecessarily obscure gist of the embodiments disclosed in the present specification, the detailed description thereof will be omitted. Further, the accompanying drawings are merely for facilitating understanding of the embodiments disclosed in the present specification, the technological scope disclosed in the present specification is not limited by the accompanying drawings, and it should be understood as including all modifications, equivalents and alternatives that fall within the spirit and scope of the present invention.

It will be understood that, although the terms “first,” “second,” etc. may be used herein to describe various elements, these elements should not be limited by these terms. These terms are only used to distinguish one element from another.

It will be understood that when an element is referred to as being “connected” or “coupled” to another element, it can be directly connected or coupled to the other element or intervening elements may be present. In contrast, when an element is referred to as being “directly connected” or “directly coupled” to another element, it will be understood that there are no intervening elements present.

As used herein, a singular expression includes a plural expression, unless the context clearly indicates otherwise.

It will be understood that the terms “comprise”, “include”, or “have” specify the presence of stated features, integers, steps, operations, elements, components and/or groups thereof disclosed in the present specification, but do not preclude the possibility of the presence or addition of one or more other features, integers, steps, operations, elements, components, and/or groups thereof.

Hereinafter, embodiments of the present invention will be described in detail with reference to the accompanying drawings.

### Comparison Example

Before describing the embodiment, a comparative example compared to the circuit board of the embodiment of the present application will be described.

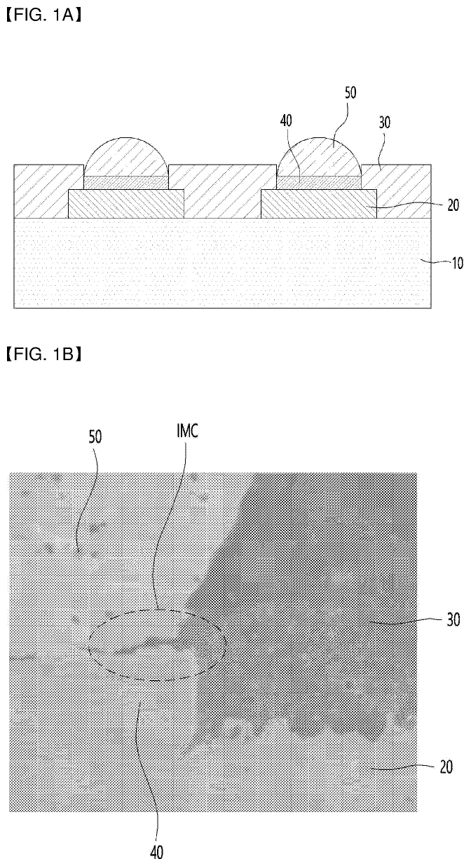

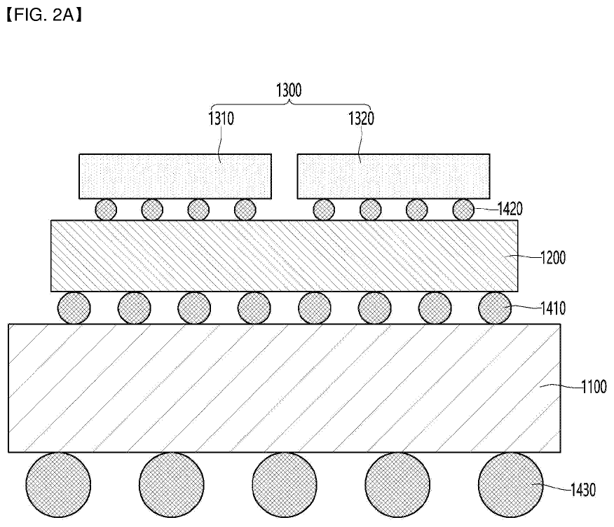

FIG. 1A is a diagram showing a circuit board according to a comparative example, and FIG. 1B is a diagram for explaining the reliability problem of a metal contact layer (IMC) in a comparative example of FIG. 1A.

Referring to FIG. 1A, the circuit board according to the comparative example includes an insulating layer 10, a circuit pattern layer 20, a protective layer 30, a surface treatment layer 40, and solder 50.

The circuit board in the comparative example has a structure in which solder 50 is disposed on the circuit pattern layer 20 to attach a semiconductor device (not shown) or an external substrate (not shown).

The circuit board of the comparative example includes an insulating layer 10. At this time, the circuit board may have a plurality of layer structures based on the number of layers of the insulating layer. In addition, when the circuit board has a plurality of layer structure, the insulating layer 10 of FIG. 1A may represent an insulating layer disposed at an outermost layer (for example, an uppermost side or a lowermost side) among the plurality of insulating layers.

The circuit board of the comparative example includes a circuit pattern layer 20 disposed on the insulating layer 10. The circuit pattern layer 20 includes pads and traces. The pad may refer to a pattern on which the solder 50 is disposed for bonding to the semiconductor device or an external substrate among the circuit pattern layers. The trace may refer to a thin signal line connecting the plurality of pads.

Additionally, the circuit board of the comparative example includes a protective layer 30 disposed on the insulating layer 10.

The protective layer 30 includes a recess portion.

The recess portion of the protective layer 30 vertically overlaps a pad of the circuit pattern layer 20 where the solder 50 is to be placed.

For example, the protective layer 30 vertically overlaps at least a portion of the circuit pattern layer 20, thereby providing a space for the solder 50 to be disposed.

A surface treatment layer 40 is disposed in the protective layer 30.

The surface treatment layer 40 is disposed in the recess portion of the protective layer 30.

For example, the surface treatment layer 40 fills a portion of the recess portion of the protective layer 30. The surface treatment layer 40 is disposed on the circuit pattern layer 20 that vertically overlaps the recess portion of the protective layer 30.

The surface treatment layer 40 may have a certain thickness.

The surface treatment layer 40 may include at least one metal layer according to a surface treatment method. For example, the surface treatment layer 40 includes a nickel (Ni) plating layer and a gold (Au) plating layer, or includes a nickel (Ni) plating layer, a palladium (Pd) plating layer, and a gold (Au) plating layer.

Meanwhile, the solder 50 is disposed on the surface treatment layer 40, filling the recess portion of the protective layer 30. At this time, the surface treatment layer 40 and the solder 50 are made of different materials, and a metal contact layer (IMC) is formed at an interface between the surface treatment layer 40 and the solder 50.

At this time, an upper surface of the protective layer 30 in the comparative example is located adjacent to the metal contact layer (IMC). At this time, the protective layer 30 contracts and expands depending on thermal characteristics, etc. in the environment in which the circuit board is used. In addition, the stress resulting from the contraction and expansion is transmitted to the metal contact layer (IMC) along the upper surface of the protective layer 30 and the inner wall of the recess portion.

In addition, the comparative example proceeds with a process of bonding a semiconductor device or a main board of an external device to the solder 50 and forming a molding layer (not shown) for molding the semiconductor device or the main board accordingly. At this time, the forming process of the molding layer is performed by injecting molding material onto the protective layer 30. At this time, during the forming process of the molding layer, a certain pressure is applied to inject the molding material, and the applied pressure is transmitted to the metal contact layer (IMC) along the inner wall of the recess portion of the protective layer 30.

At this time, in the comparative example as described above, the upper surface of the protective layer 30 and the metal contact layer (IMC) are located adjacent to each other, and accordingly, the generated stress or pressure is directly transmitted to the metal contact layer (IMC).

And, as shown in FIG. 1B, when the stress or pressure is transmitted to the metal contact layer (IMC), there is a problem that cracks occur in the metal contact layer (IMC) due to the transmitted pressure. Additionally, when a crack occurs in the metal contact layer (IMC), a physical reliability problem occurs in which the solder 50 is separated from the surface treatment layer 40.

In addition, when the solder 50 is separated from the surface treatment layer 40, the semiconductor device or main board connected to the solder 50 is also separated from the circuit board, resulting in a problem with product reliability.

Accordingly, the embodiment solves the physical reliability problem of the circuit board of the comparative example. Specifically, the embodiment increases the distance between the upper surface of the protective layer and the metal contact layer (IMC) without increasing the thickness of the circuit board. Specifically, the embodiment increases the distance between the inner wall of the recess portion of the protective layer connecting the upper surface of the protective layer and the metal contact layer (IMC).

Through this, the embodiment allows to stably protect the metal contact layer (IMC) from the generated stress or pressure, and thus allows to improve the physical reliability of the metal contact layer (IMC). For example, the embodiment allows the inner wall length between one end connected to the metal contact layer (IMC) and the other end connected to the upper surface of the protective layer to be increased in the inner wall of the recess portion of the protective layer, and allows damage caused by the stress or pressure to not be transmitted directly to the metal contact layer (IMC). Through this, the embodiment allows to improve the physical reliability of the metal contact layer.

### Electronic Device

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one chip. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

Hereinafter, a semiconductor package including a circuit board according to an embodiment will be described. The semiconductor package of the embodiment may have various package structures including a circuit board to be described later.

In addition, a circuit board in one embodiment may be a first board described below.

In addition, a circuit board in another embodiment may be a second board described below.

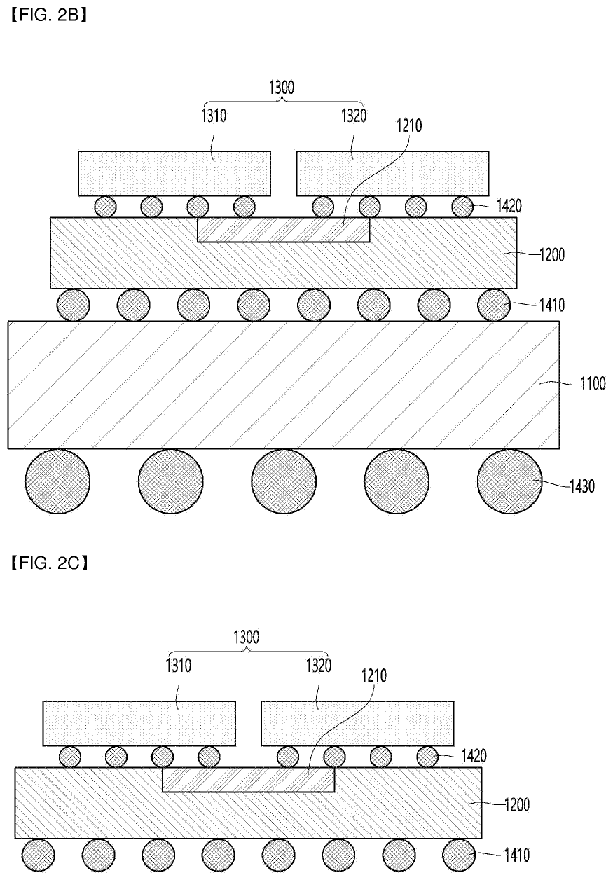

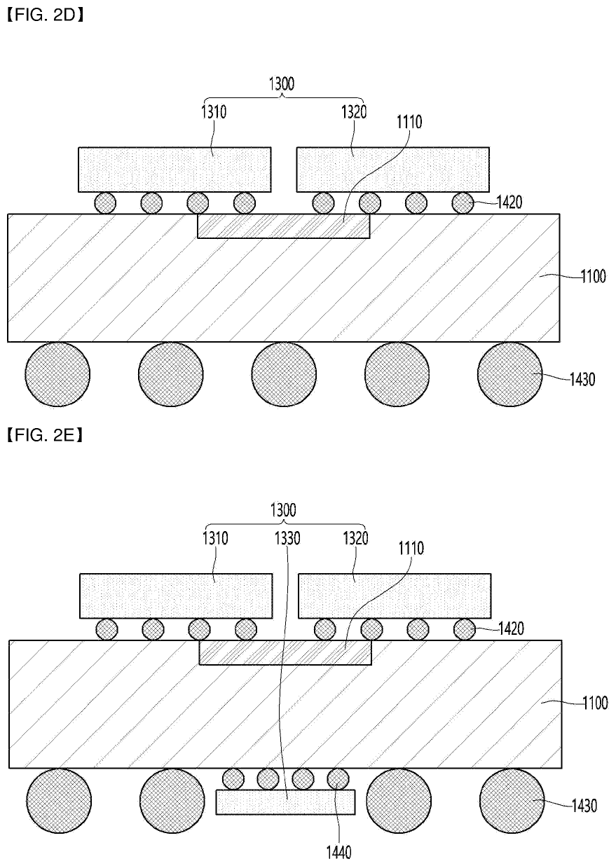

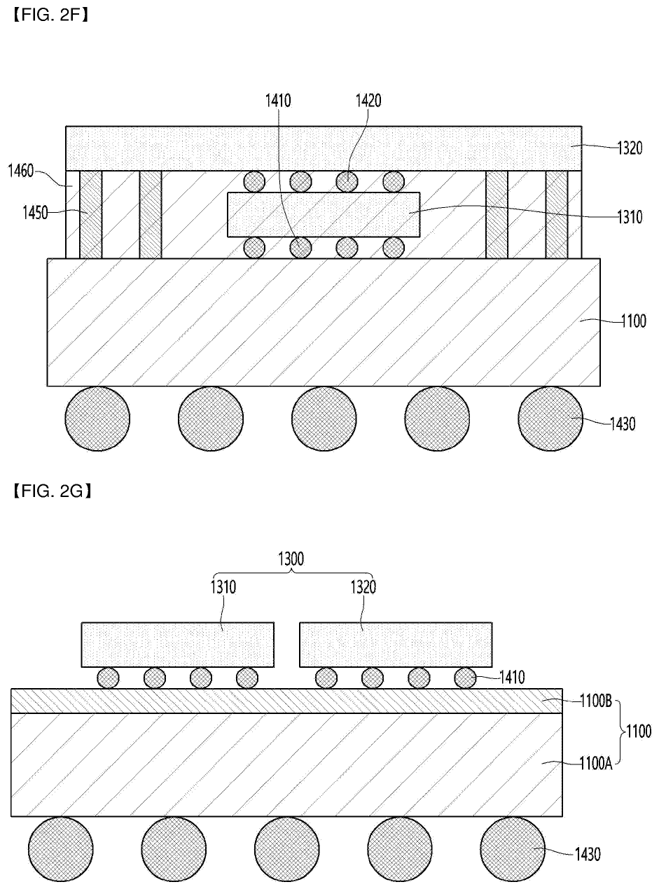

FIG. 2A is a cross-sectional view illustrating a semiconductor package according to a first embodiment, FIG. 2B is a cross-sectional view illustrating a semiconductor package according to a second embodiment, FIG. 2C is a cross-sectional view illustrating a semiconductor package according to a third embodiment, FIG. 2D is a cross-sectional view illustrating a semiconductor package according to a fourth embodiment, FIG. 2E is a cross-sectional view illustrating a semiconductor package according to a fifth embodiment, FIG. 2F is a cross-sectional view illustrating a semiconductor package according to a sixth embodiment, and FIG. 2G is a cross-sectional view illustrating a semiconductor package according to a seventh embodiment.

Referring to FIG. 2A, the semiconductor package according to the first embodiment may include a first circuit board 1100, a second circuit board 1200, and a semiconductor device 1300.

The first circuit board 1100 may mean a package substrate.

For example, the first circuit board 1100 may provide a space to which at least one external substrate is coupled. The external substrate may refer to a second circuit board 1200 coupled to the first circuit board 1100. Also, the external substrate may refer to a main board included in an electronic device coupled to a lower portion of the first circuit board 1100.

Also, although not shown in the drawing, the first circuit board 1100 may provide a space in which at least one semiconductor device is mounted.

The first circuit board 1100 may include at least one insulating layer, an electrode part disposed on the at least one insulating layer, and a via passing through the at least one insulating layer.

A second circuit board 1200 may be disposed on the first circuit board 1100.

The second circuit board 1200 may be an interposer. For example, the second circuit board 1200 may provide a space in which at least one semiconductor device is mounted. The second circuit board 1200 may be connected to the at least one semiconductor device 1300. For example, the second circuit board 1200 may provide a space in which the first semiconductor device 1310 and the second semiconductor device 1320 are mounted. The second circuit board 1200 may electrically connect the first and second semiconductor devices 1310 and 1320 and the first circuit board 1100 while electrically connecting the first semiconductor device 1310 and the second semiconductor device 1320. That is, the second circuit board 1200 may perform a horizontal connection function between a plurality of semiconductor devices and a vertical connection function between the semiconductor devices and the package substrate.

FIG. 2A illustrates that the first and second semiconductor devices 1310 and 1320 are disposed on the second circuit board 1200, but is not limited thereto. For example, one semiconductor device may be disposed on the second circuit board 1200, or alternatively, three or more semiconductor devices may be disposed.

The second circuit board 1200 may be disposed between at least one of the semiconductor device 1300 and the first circuit board 1100.

In one embodiment, the second circuit board 1200 may be an active interposer that functions as a semiconductor device. When the second circuit board 1200 functions as a semiconductor device, the semiconductor package of the embodiment may have a vertical stack structure on the first circuit board 1100 and function as a plurality of logic chips. Being able to have the functions of a logic chip may mean having the functions of an active device and a passive device. In the case of active devices, unlike passive devices, current and voltage characteristics may not be linear, and in the case of an active interposer, it can have the function of an active device. Additionally, the active interposer may function as a corresponding logic chip and perform a signal transmission function between the first circuit board 1100 and a second logic chip disposed on an upper portion of the active interposer.

According to another embodiment, the second circuit board 1200 may be a passive interposer. For example, the second circuit board 1200 may function as a signal relay between the semiconductor device 1300 and the first circuit board 1100, and may have passive device functions such as a resistor, capacitor, and inductor. For example, a number of terminals of the semiconductor device 1300 is gradually increasing due to 5G, Internet of Things (IOT), increased image quality, and increased communication speed. That is, the number of terminals provided in the semiconductor device 1300 increases, thereby reducing the width of the terminals or an interval between the plurality of terminals. In this case, the first circuit board 1100 may be connected to the main board of the electronic device. There is a problem in that the thickness of the first circuit board 1100 increases or the layer structure of the first circuit board 1100 becomes complicated in order for the electrodes provided on the first circuit board 1100 to have a width and an interval to be respectively connected to the semiconductor device 1300 and the main board. Accordingly, in the first embodiment, the second circuit board 1200 may be disposed on the first circuit board 1100 and the semiconductor device 1300. In addition, the second circuit board 1200 may include electrodes having a fine width and an interval corresponding to the terminals of the semiconductor device 1300.

the semiconductor device 1300 may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far. The memory chip may be a stack memory such as HBM. The memory chip may also include a memory chip such as volatile memory (e.g., DRAM), non-volatile memory (e.g., ROM), flash memory, and the like.

Meanwhile, the semiconductor package of the first embodiment may include a connection part.

For example, the semiconductor package may include a first connection part 1410 disposed between the first circuit board 1100 and the second circuit board 1200. The first connection part 1410 may electrically connect the second circuit board 1200 to the first circuit board 1100 while coupling them.

For example, the semiconductor package may include the second connection part 1420 disposed between the second circuit board 1200 and the semiconductor device 1300. The second connection part 1420 may electrically connect the semiconductor device 1300 to the second circuit board 1200 while coupling them.

The semiconductor package may include a third connection part 1430 disposed on a lower surface of the first circuit board 1100. The third connection part 1430 may electrically connect the first circuit board 1100 to the main board while coupling them.

At this time, the first connection part 1410, the second connection part 1420, and the third connection part 1430 may electrically connect between the plurality of components by using at least one bonding method of wire bonding, solder bonding and metal-to-metal direct bonding. That is, since the first connection part 1410, the second connection part 1420, and the third connection part 1430 have a function of electrically connecting a plurality of components, when the metal-to-metal direct bonding is used, the connection part of the semiconductor package may be understood as an electrically connected portion, not a solder or wire.

The wire bonding method may refer to electrically connecting a plurality of components using a conductive wire such as gold (Au). Also, the solder bonding method may electrically connect a plurality of components using a material containing at least one of Sn, Ag, and Cu. In addition, the metal-to-metal direct bonding method may refer to recrystallization by applying heat and pressure between a plurality of components without the presence of solder, wire, conductive adhesive, etc. and to directly bond between the plurality of components. In addition, the metal-to-metal direct bonding method may refer to a bonding method by the second connection part 1420. In this case, the second connection part 1420 may mean a metal layer formed between a plurality of components by the recrystallization.

Specifically, the first connection part 1410, the second connection part 1420, and the third connection part 1430 may couple a plurality of components to each other by a thermal compression (TC) bonding method. The TC bonding may refer to a method of directly coupling a plurality of components by applying heat and pressure to the first connection part 1410, the second connection part 1420, and the third connection part 1430.

In this case, at least one of the first circuit board 1100 and the second circuit board 1200 may include a protrusion provided on the electrode where the first connection part 1410, the second connection part 1420, and the third connection part 1430 are disposed, and protruding in an outward direction away from the insulating layer of the corresponding circuit board. The protrusion may protrude outward from the first circuit board 1100 or the second circuit board 1200.

The protrusion may be referred to as a bump. The protrusion may also be referred to as a post. The protrusion may also be referred to as a pillar. Preferably, the protrusion may refer to an electrode on which a second connection part 1420 for coupling with the semiconductor device 1300 is disposed among the electrodes of the second circuit board 1200. That is, the pitch of the terminals of the semiconductor device 1300 is becoming finer, as a result, a short circuit may occur between the plurality of second connection parts 1420 respectively connected to the plurality of terminals of the semiconductor device 1300 by a conductive adhesive such as solder. Accordingly, the embodiment may perform thermal compression bonding to reduce the volume of the second connection part 1420. Accordingly, the embodiment may include a protrusion in the electrode of the second circuit board 1200 on which the second connection part 1420 is disposed in order to secure position accuracy and diffusion prevention power to prevent the intermetallic compound (IMC) formed between a conductive adhesive such as solder and a protrusion from diffusing to the interposer and/or the circuit board.

Meanwhile, referring to FIG. 2B, the semiconductor package of the second embodiment may differ from the semiconductor package of the first embodiment in that the connecting member 1210 is disposed on the second circuit board 1200. The connecting member 1210 may be referred to as a bridge substrate. For example, the connecting member 1210 may include a redistribution layer. The connecting member 1210 may function to electrically connect a plurality of semiconductor devices to each other horizontally. For example, an area that a semiconductor device should have, is generally too large, and for this reason, the connecting member 1210 may include a redistribution layer. The semiconductor package and the semiconductor device have significant differences in a width and a spacing of their circuit patterns, and for this reason, a buffering role of the circuit pattern for electrical connection is necessary. The buffering role may mean having an intermediate size between the width or spacing of the circuit pattern of the semiconductor package and the width or spacing of the circuit pattern of the semiconductor device, and the redistribution layer may include a function that acts as a buffer.

In an embodiment, the connecting member 1210 may be a silicon bridge. That is, the connecting member 1210 may include a silicon substrate and a redistribution layer disposed on the silicon substrate.

In another embodiment, the connecting member 1210 may be an organic bridge. For example, the connecting member 1210 may include an organic material. For example, the connecting member 1210 may include an organic substrate including an organic material instead of the silicon substrate.

The connecting member 1210 may be embedded in the second circuit board 1200, but is not limited thereto. For example, the connecting member 1210 may be disposed on the second circuit board 1200 to have a protruding structure.

Also, the second circuit board 1200 may include a cavity, and the connecting member 1210 may be disposed in the cavity of the second circuit board 1200.

The connecting member 1210 may horizontally connect a plurality of semiconductor devices disposed on the second circuit board 1200.

Referring to FIG. 20, the semiconductor package according to the third embodiment may include a second circuit board 1200 and a semiconductor device 1300. In this case, the semiconductor package of the third embodiment may have a structure in which the first circuit board 1100 is removed compared to the semiconductor package of the second embodiment.

That is, the second circuit board 1200 of the third embodiment may function as a package substrate while performing an interposer function.

The first connection part 1410 disposed on the lower surface of the second circuit board 1200 may couple the second circuit board 1200 to the main board of the electronic device.

Referring to FIG. 2D, the semiconductor package according to the fourth embodiment may include a first circuit board 1100 and a semiconductor device 1300.

In this case, the semiconductor package of the fourth embodiment may have a structure in which the second circuit board 1200 is omitted compared to the semiconductor package of the second embodiment.

That is, the first circuit board 1100 of the fourth embodiment may function as a connection between the semiconductor device 1300 and the main board while functioning as a package substrate. To this end, the first circuit board 1100 may include a connecting member 1110 for connecting the plurality of semiconductor devices. The connecting member 1110 may be a silicon bridge or an organic material bridge connecting a plurality of semiconductor devices.

Referring to FIG. 2E, the semiconductor package of the fifth embodiment may further include a third semiconductor device 1330 compared to the semiconductor package of the fourth embodiment.

To this end, a fourth connection part 1440 may be disposed on the lower surface of the first circuit board 1100.

In addition, a third semiconductor device 1330 may be disposed on the fourth connection part 1400. That is, the semiconductor package of the fifth embodiment may have a structure in which semiconductor devices are mounted on upper and lower sides, respectively.

In this case, the third semiconductor device 1330 may have a structure disposed on the lower surface of the second circuit board 1200 in the semiconductor package of FIG. 2C.

Referring to FIG. 2F, the semiconductor package according to the sixth embodiment may include a first circuit board 1100. A first semiconductor device 1310 may be disposed on the first circuit board 1100. To this end, a first connection part 1410 may be disposed between the first circuit board 1100 and the first semiconductor device 1310.

In addition, the first circuit board 1100 may include a conductive coupling portion 1450. The conductive coupling portion 1450 may further protrude from the first circuit board 1100 toward the second semiconductor device 1320. The conductive coupling portion 1450 may be referred to as a bump or, alternatively, may also be referred to as a post. The conductive coupling portion 1450 may be disposed to have a protruding structure on an electrode disposed on an uppermost side of the first circuit board 1100.

A second semiconductor device 1320 may be disposed on the conductive coupling portion 1450. In this case, the second semiconductor device 1320 may be connected to the first circuit board 1100 through the conductive coupling portion 1450. In addition, a second connection part 1420 may be disposed on the first semiconductor device 1310 and the second semiconductor device 1320.

Accordingly, the second semiconductor device 1320 may be electrically connected to the first semiconductor device 1310 through the second connection part 1420.

That is, the second semiconductor device 1320 may be connected to the first circuit board 1100 through the conductive coupling portion 1450, and may be also connected to the first semiconductor device 1310 through the second connection part 1420.

In this case, the second semiconductor device 1320 may receive a power signal and/or an electrical power through the conductive coupling portion 1450. Also, the second semiconductor device 1320 may transmit and receive a communication signal to and from the first semiconductor device 1310 through the second connection part 1420.

The semiconductor package according to the sixth embodiment provides a power signal and/or an electrical power to the second semiconductor device 1320 through the conductive coupling portion 1450, and it may be possible to provide sufficient power for driving the second semiconductor device 1320 or to smoothly control power supply operation.

Accordingly, the embodiment may improve the driving characteristics of the second semiconductor device 1320. That is, the embodiment may solve the problem of insufficient power provided to the second semiconductor device 1320. Furthermore, in the embodiment, at least one of the power signal, the electrical power and the communication signal of the second semiconductor device 1320 may be provided through different paths through the conductive coupling portion 1450 and the second connection part 1420. Through this, the embodiment can solve the problem that the communication signal is lost due to the power signal. For example, the embodiment may minimize mutual interference between communication signals of power signals.

Meanwhile, the second semiconductor device 1320 in the sixth embodiment may have a POP (Package On Package) structure in which a plurality of package substrates are stacked and may be disposed on the first substrate 1100. For example, the second semiconductor device 1320 may be a memory package including a memory chip. In addition, the memory package may be coupled on the conductive coupling portion 1450. In this case, the memory package may not be connected to the first semiconductor device 1310.

Meanwhile, the semiconductor package in the sixth embodiment may include a molding member 1460. The molding member 1460 may be disposed between the first circuit board 1100 and the second semiconductor device 1320. For example, the molding member 1460 may mold the first connection member 1410, the second connection member 1420, the first semiconductor device 1310, and the conductive coupling portion 1450.

Referring to FIG. 2G, the semiconductor package according to the seventh embodiment may include a first circuit board 1100, a first connection part 1410, a first connection part 1410, a semiconductor device 1300, and a third connection part 1430.

In this case, the semiconductor package of the seventh embodiment is different from the semiconductor package of the fourth embodiment in that the first circuit board 1100 includes a plurality of substrate layers while the connecting member 1110 is removed.

The first circuit board 1100 includes a plurality of substrate layers. For example, the first circuit board 1100 may include a first substrate layer 1100A corresponding to a package substrate and a second substrate layer 1100B corresponding to the connecting member.

In other words, the semiconductor package of the seventh embodiment may include a first substrate layer 1100A and a second substrate layer 1100B in which the first circuit board (package substrate, 1100) and the second circuit board (interposer, 1200) shown in FIG. 2A are integrally formed. The material of the insulating layer of the second substrate layer 1100B may be different from the material of the insulating layer of the first substrate layer 1100A. For example, the material of the insulating layer of the second substrate layer 1100B may include a photocurable material. For example, the second substrate layer 1100B may be a photo imageable dielectric (PID). In addition, since the second substrate layer 1100B includes a photocurable material, it is possible to miniaturize the electrode. Accordingly, in the seventh embodiment, the second substrate layer 1100B may be formed by sequentially stacking an insulating layer of a photo-curable material on the first substrate layer 1100A and forming a miniaturized electrode on the insulating layer of the photo-curable material. Through this, the second circuit board 1100B may be a redistribution layer including a miniaturized electrode and include a function to horizontally connect a plurality of semiconductor devices 1310 and 1320.

### Circuit Board of First Embodiment

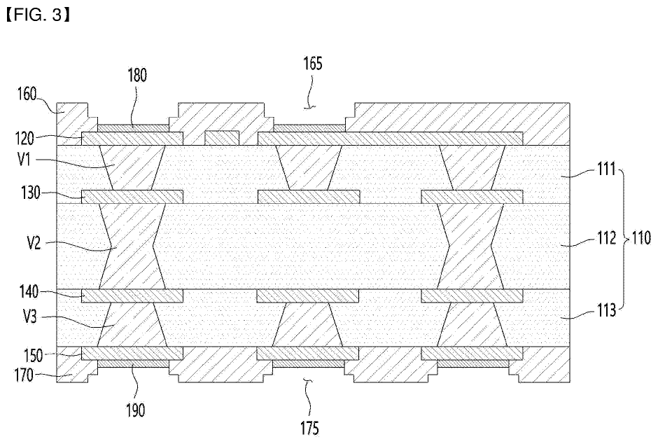

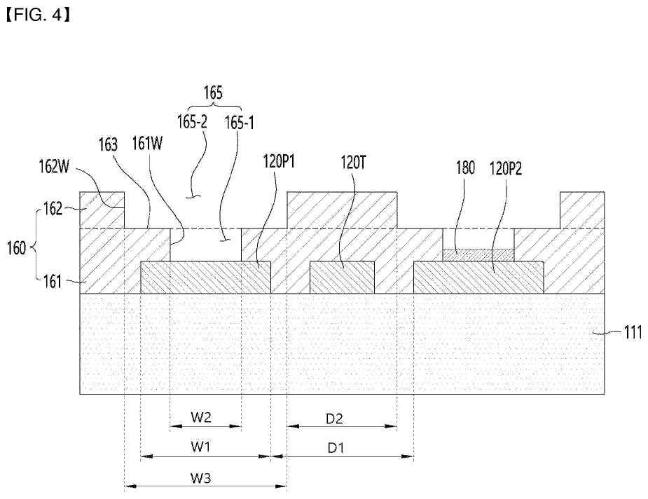

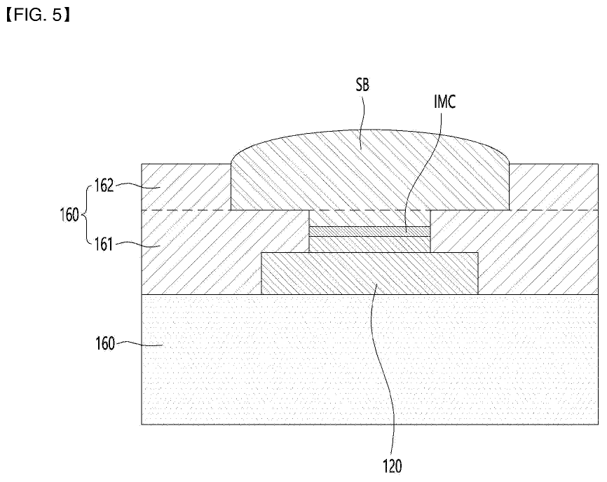

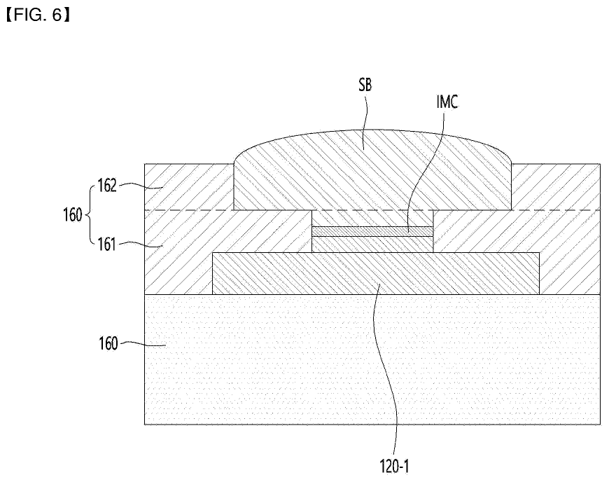

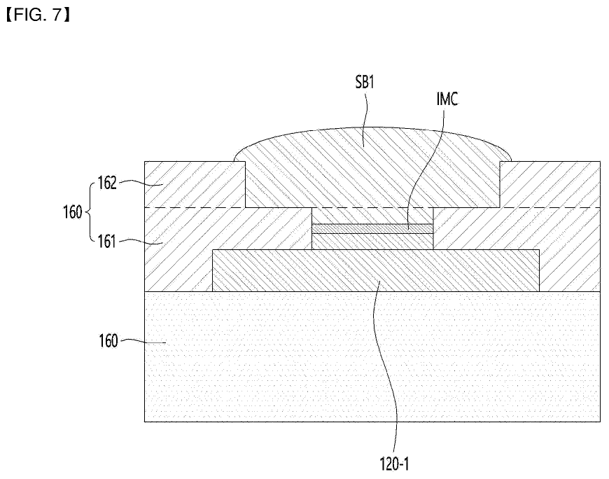

FIG. 3 is a diagram showing a circuit board according to the first embodiment, FIG. 4 is an enlarged view of one region of the circuit board of FIG. 3, FIG. 5 is a diagram for explaining the reliability of a metal contact layer according to a first embodiment, FIG. 6 is a diagram showing a first modified example of the circuit board of FIG. 3, FIG. 7 is a diagram showing a second modified example of the circuit board of FIG. 3, and FIG. 8 is a diagram showing a third modified example of the circuit board of FIG. 3.

Below, the circuit board of the embodiment will be described.

Before describing the circuit board of the embodiment, a circuit board described below may refer to any one circuit board among a plurality of circuit boards included in a previous semiconductor package.

For example, the circuit board described below may refer to any one of the first circuit board 1100, the second circuit board 1200, and the connection member (or bridge board, 1110, 1210) shown in any one of FIGS. 2A to 2G.

Hereinafter, the circuit board according to the first embodiment will be described in detail with reference to FIGS. 3 to 8.

Referring to FIGS. 3 to 8, the circuit board includes an insulating layer 110, a circuit pattern layer, a via, a protective layer and surface treatment layer.

For example, an insulating layer 110 may include a first insulating layer 111, a second insulating layer 112, and a third insulating layer 113. At this time, the circuit board is shown in the drawing as having a three-layer structure based on the number of insulating layers, but it is not limited thereto. For example, the circuit board may have a structure of two or less layers based on the number of insulating layers. For example, a circuit board may have a single-layer structure based on the number of insulating layers. For example, a circuit board may have a structure of four or more layers based on the number of insulating layers.

For example, the first insulating layer 111 may be a first outermost insulating layer disposed at an first outermost side in a multi-layer structure. For example, the first insulating layer 111 may be an insulating layer disposed at an uppermost side of the circuit board. The second insulating layer 112 may be an inner insulating layer disposed at an inside of a multi-layered circuit board. The third insulating layer 113 may be a second outermost insulating layer disposed at the second outermost side in a multi-layer structure. For example, the third insulating layer 113 may be an insulating layer disposed at a lowermost side of the circuit board. In addition, the inner insulating layer is shown as consisting of one layer, if the circuit board has a layer structure of four or more layers, the inner insulating layer may have a layer structure of two or more layers.

The insulating layer 110 is a board equipped with an electric circuit whose wiring can be changed, and may include a print, a wiring board, and an insulating board made of an insulating material capable of forming circuit patterns on the surface.

For example, at least one of the insulating layer 110 may be rigid or flexible. For example, at least one of the insulating layer 110 may include glass or plastic. Specifically, the insulating layer 110 may include a chemically tempered/semi-tempered glass, such as soda lime glass, aluminosilicate glass, etc., a tempered or flexible plastic such as polyimide (PI), polyethylene terephthalate (PET), propylene glycol (PPG), polycarbonate (PC), etc., or sapphire.

In addition, at least one of the insulating layer 110 may include an optically isotropic film. For example, at least one of the insulating layer 110 may include cyclic olefin copolymer (COC), cyclic olefin polymer (COP), optically isotropic PC, optically isotropic polymethylmethacrylate (PMMA), or the like.

In addition, at least one of the insulating layer 110 may be formed of a material including an inorganic filler and an insulating resin. For example, at least one of the insulating layer 330 may be formed of a resin containing reinforcing materials such as inorganic fillers such as silica and alumina together with a thermosetting resin such as an epoxy resin or a thermoplastic resin such as polyimide, specifically Ajinomoto Build-up Film (ABF), FR-4, Bismaleimide Triazine (BT), Photo Imageable Dielectric resin (PID), BT, or the like.

In addition, at least one of the insulating layers 110 may have a partially curved surface and be curved. That is, at least one of the insulating layers 110 is partially flat, and at least one of the insulating layers 110 may have a partially curved surface and be bent. In detail, at least one end of the insulating layer 110 may have a curved surface and be bent, or at least one end of the insulating layer 110 has a surface with random curvature and may be curved or bent.

A circuit pattern layer may be disposed on a surface of the insulating layer 110.

For example, a first circuit pattern layer 120 may be disposed on a first or upper surface of the first insulating layer 111. For example, a second circuit pattern layer 130 may be disposed between a second surface or lower surface of the first insulating layer 111 and a first surface or upper surface of the second insulating layer 112. For example, a third circuit pattern layer 140 may be disposed between a second surface or lower surface of the second insulating layer 112 and a first surface or upper surface of the third insulating layer 113. For example, a fourth circuit pattern layer 150 may be disposed on a second or lower surface of the third insulating layer 113. A first circuit pattern layer 120 may be a circuit pattern layer disposed at a first outermost side or uppermost side of the circuit board. Additionally, the second circuit pattern layer 130 and the third circuit pattern layer 140 may be inner circuit pattern layers disposed inside the circuit board. Additionally, the fourth circuit pattern layer 150 may be a circuit pattern layer disposed at a second outermost side or lowermost side of the circuit board.

The first circuit pattern layer 120, the second circuit pattern layer 130, the third circuit pattern layer 140, and the fourth circuit pattern layer 150 is a wire that transmits electrical signals and may be formed of a metal material with high electrical conductivity. The first circuit pattern layer 120, the second circuit pattern layer 130, the third circuit pattern layer 140, and the fourth circuit pattern layer 150 may be formed of at least one metal material selected from among gold (Au), silver (Ag), platinum (Pt), titanium (Ti), tin (Sn), copper (Cu), and zinc (Zn). In addition, the first circuit pattern layer 120, the second circuit pattern layer 130, the third circuit pattern layer 140, and the fourth circuit pattern layer 150 may be formed of paste or solder paste including at least one metal material selected from among gold (Au), silver (Ag), platinum (Pt), titanium (Ti), tin (Sn), copper (Cu), and zinc (Zn), which are excellent in bonding force. Preferably, the first circuit pattern layer 120, the second circuit pattern layer 130, the third circuit pattern layer 140, and the fourth circuit pattern layer 150 may be formed of copper (Cu) having high electrical or thermal conductivity and a relatively low cost.

The first circuit pattern layer 120, the second circuit pattern layer 130, the third circuit pattern layer 140, and the fourth circuit pattern layer 150 can be formed using an additive process, a subtractive process, a modified semi additive process (MSAP) and a semi additive process (SAP), which is a typical circuit board manufacturing process, and a detailed description will be omitted here.

The first circuit pattern layer 120 may have a thickness ranging from 5 μm to 30 μm. For example, the first circuit pattern layer may have a thickness ranging from 6 μm to 25 μm. The first circuit pattern layer may have a thickness ranging from 7 μm to 20 μm. If the thickness of the first circuit pattern layer 120 is less than 5 μm, resistance of the circuit pattern increases, and signal transmission efficiency may decrease accordingly. For example, when if thickness of the first circuit pattern layer 120 is less than 5 μm, signal transmission loss may increase. For example, when the thickness of the first circuit pattern layer 120 exceeds 30 μm, a line width of the trace 120T of the first circuit pattern layer 120 may increase, and thus the overall volume of the circuit board may increase.

The second circuit pattern layer 130, the third circuit pattern layer 140, and the fourth circuit pattern layer 150 may each have a thickness corresponding to the thickness of the first circuit pattern layer 120.

Meanwhile, each of the first to fourth circuit pattern layers 120, 130, 140, and 150 includes traces and pads.

The trace refers to a long line-shaped wiring that transmits electrical signals. Additionally, the pad may refer to a mounting pad on which components such as semiconductor devices are mounted, a core pad or BGA pad for connection to an external board, or a via pad connected to a via.

A via may be formed in the insulating layer 110. The via is formed to pass through the insulating layer 110, and thus can electrically connect circuit pattern layers arranged in different layers.

For example, a first via V1 may be formed in the first insulating layer 111. The first via V1 passes through the first insulating layer 111, and thus can electrically connect the first circuit pattern layer 120 and the second circuit pattern layer 130.

For example, a second via V2 may be formed in the second insulating layer 112. The second via V2 passes through the second insulating layer 112, and thus can electrically connect the second circuit pattern layer 130 and the third circuit pattern layer 140. At this time, the second insulating layer 112 may be a core layer. And, when the second insulating layer 112 is a core layer, the second via V2 may have an hourglass shape, but the embodiment is not limited thereto. For example, when the circuit board of the embodiment is a coreless board, the second via V2 may have a same shape as the first via V1 or the third via V3.

For example, a third via V3 may be formed in the third insulating layer 113. The third via V3 passes through the third insulating layer 113, and thus can electrically connect the third circuit pattern layer 140 and the fourth circuit pattern layer 150.

The vias V1, V2 and V3 as described above may be formed by filling the inside of a through hole formed in each insulating layer with a metal material. The through hole may be formed by any one of mechanical, laser, and chemical processing. When the via hole is formed by mechanical processing, a method such as milling, drilling and routing may be used, when the via hole is formed by laser processing, a method of UV or CO2 laser may be used, when the via hole is formed by chemical processing, a chemical including amino silane, ketones, or the like may be used. Accordingly, at least one insulating layer among the plurality of insulating layers may be opened.

When the through hole is formed, the vias V1, V2, and V3 may be formed by filling the inside of the through hole with a conductive material. The metal material forming the vias V1, V2, and V3 may be any one selected from among copper (Cu), silver (Ag), tin (Sn), gold (Au), nickel (Ni), and palladium (Pd). In addition, the conductive material may be filled by any one of electroless plating, electroplating, screen printing, sputtering, evaporation, ink jetting, and dispensing, or a combination thereof.

Meanwhile, a first protective layer 160 may be disposed on a first surface or an upper surface of the first insulating layer 111. The first protective layer 160 may include a solder resist. The first protective layer 160 may include a recess portion 165 that vertically overlaps the first circuit pattern layer 120. For example, the first circuit pattern layer 120 that vertically overlaps the recess portion 165 of the first protective layer 160 may mean a mounting pad on which a semiconductor device is mounted.

The first protective layer 160 may include a recess portion 165 that vertically overlaps the pad of the first circuit pattern layer 120. At this time, embodiments of the circuit board of the present application can be classified according to a shape of the recess portion of the first protective layer of the circuit board.

For example, the recess portion of the first protective layer may be divided into first to third types. However, the first to third types of recess portions include common features. For example, in an embodiment, the recess portion 165 of the first protective layer 160 may have a step. The step of the recess portion 165 increases the distance between the first protective layer 160 and a metal contact layer (IMC) formed as later solder is placed, and the step can function to improve the physical reliability of the metal contact layer (IMC).

Additionally, a second protective layer 170 may be disposed on the second surface of the third insulating layer 113. The second protective layer 170 may include a solder resist. The second protective layer 170 may include a recess portion 175 that vertically overlaps a pad (not shown) of the fourth circuit pattern layer 150.

At this time, the first protective layer 160 and the second protective layer 170 are merely disposed at different positions, and but their basic structures described below may be the same. For example, the recess portion 175 of the second protective layer 170 may have a step. In addition, the step of the recess portion 175 of the second protective layer 170 is the distance between the metal contact layer (IMC) formed as the solder is disposed later and the lower surface of the second protective layer 160. increases, and accordingly, the step the recess portion 175 can function to improve the physical reliability of the metal contact layer (IMC).

Meanwhile, a first surface treatment layer 180 may be disposed in the recess portion 165 of the first protective layer 160. The first surface treatment layer 180 may fill a portion of the recess portion 165 of the first protective layer 160. At this time, in the embodiment, an upper surface of the first surface treatment layer 180 may be located lower than a step portion of the recess portion 165 of the first protective layer 160. For example, an upper surface of the first surface treatment layer 180 may be located lower than a position where the step of the recess portion 165 of the first protective layer 160 is formed. Through this, in the embodiment, the physical reliability of the metal contact layer (IMC) formed as the solder is disposed on the first surface treatment layer 180 can be improved.

Additionally, a second surface treatment layer 190 may be disposed within the recess portion 175 of the second protective layer 170. The second surface treatment layer 190 may fill a portion of the recess portion 175 of the second protective layer 170. At this time, a lower surface of the second surface treatment layer 190 may be positioned higher than a step portion of the recess portion 175 of the second protective layer 170. For example, a lower surface of the second surface treatment layer 190 may be positioned higher than the position where the step of the recess portion 195 of the second protective layer 170 is formed. Through this, in the embodiment, the physical reliability of the metal contact layer (IMC) formed as the solder is disposed under the second surface treatment layer 190 can be improved.

Hereinafter, the recess portion of the first protective layer 160 and the second protective layer 170 according to the embodiment will be described in detail.

At this time, the recess portion 165 of the first protective layer 160 and the recess portion 175 of the second protective layer 170 in the embodiment may include substantially the same characteristics. Accordingly, a following description will focus on the recess portion 165 of the first protective layer 160. However, a recess portion 175 may be formed in the second protective layer 170 to correspond to the characteristics of the recess portion 165 of the first protective layer 160.

Referring to FIG. 4, the first protective layer 160 in the embodiment may have a stepped structure.

For example, the first protective layer 160 may include a first portion 161 disposed on an upper surface of the first insulating layer 111 and a second portion 162 disposed on the first portion 161.

The first portion 161 and the second portion 162 of the first protective layer 160 may be distinguished based on the recess portion 165 provided in the first protective layer 160.

For example, the recess portion 165 may include a point where the width changes in a vertical direction. In this case, the first portion 161 of the first protective layer 160 may mean a region from the lower surface of the first protective layer 160 to the point where the width changes, and the second portion 162 of the first protective layer 160 may refer to a region from the upper surface of the first protective layer 160 to the point where the width changes.

At this time, a width of the recess portion 165 may change with a certain inclination in the vertical direction. In this case, the point may mean a point at which a inclination changes on the inner wall of the recess portion 165.

Additionally, the width of the recess portion 165 may change with a certain curvature in the vertical direction. In this case, the point may mean a point at which the curvature changes at an inner wall of the recess portion 165.

At this time, the first portion 161 of the first protective layer 160 may contact an upper surface of the first insulating layer 111. Additionally, the first portion 161 of the first protective layer 160 may contact the side surface of the first circuit pattern layer 120. Additionally, the first portion 161 of the first protective layer 160 may contact the upper surface of the first circuit pattern layer 120.

Specifically, a thickness of the first portion 161 of the first protective layer 160 may be greater than a thickness of the first circuit pattern layer 120. Accordingly, the upper surface of the first portion 161 of the first protective layer 160 may be positioned higher than the upper surface of the first circuit pattern layer 120.

Accordingly, the first portion 161 of the first protective layer 160 may cover at least a portion of the upper surface of the first circuit pattern layer 120.

The second portion 162 of the first protective layer 160 may be disposed on the first portion 161 of the first protective layer 160. At this time, an area of the second portion 162 of the first protective layer 160 may be smaller than an area of the first portion 161 of the first protective layer 160. Accordingly, the upper surface of the first portion 161 of the first protective layer 160 includes an overlapping region that vertically overlaps the second portion 162 of the first protective layer 160, and a non-overlapping region that does not vertically overlap the second portion 162 of the first protective layer 160.

A recess portion 160 may be formed in the first protective layer 160.

At this time, the recess portion 165 may be divided into a plurality of parts.

For example, the recess portion 165 may include a first part 165-1 formed

in the first portion 161 of the first protective layer 160. Specifically, the first circuit pattern layer 120 includes a pad. For example, the first circuit pattern layer 120 may include a first pad 120P1 and a second pad 120P2.

In addition, the first portion 161 of the first protective layer 160 may include a first part 165-1 of the recess portion 165 that vertically overlaps the first pad 120P1 and the second pad 120P2 of the first circuit pattern layer 120. Hereinafter, the recess portion 165 formed around the first pad 120P1 will be described. For example, the description below is about the first part 165-1 of the recess portion 165 formed in the first portion 161 of the first protective layer 160, and the second part of the recess portion 165 formed in the second portion 162 of the first protective layer 160. However, the first part 165-1 and the second part of the recess portion 165 formed around the first pad 120P1 may also be formed on the second pad 120P2 of the first circuit pattern layer 120.

A width W2 of the first part 165-1 of the recess portion 165 formed in the first portion 161 of the first protective layer 160 may be smaller than the width W1 of the first pad 120P1 of the first circuit pattern layer 120. For example, a width W2 of the first part 165-1 of the recess portion 165 formed in the first portion 161 of the first protective layer 160 may satisfy a range of 60% to 95% of the width W1 of the first pad 120P1 of the first circuit pattern layer 120. For example, a width W2 of the first part 165-1 of the recess portion 165 formed in the first portion 161 of the first protective layer 160 may satisfy a range of 65% to 93% of the width W2 of the first pad 120P1 of the first circuit pattern layer 120. For example, the width W2 of the first part 165-1 of the recess portion 165 formed in the first portion 161 of the first protective layer 160 may satisfy a range of 68% to 90% of the width W2 of the first pad 120P1 of the first circuit pattern layer 120.

At this time, if the width W2 of the first part 165-1 of the recess portion 165 formed in the first portion 161 of the first protective layer 160 is smaller than 60% of the width W1 of the first pad 120P1 of the first circuit pattern layer 120, a bonding area between the surface treatment layer 180 disposed in the first part 165-1 and the first pad 120P1 is reduced, and accordingly, the physical reliability of separating the surface treatment layer 180 from the first pad 120P1 may be reduced.

In addition, if the width W2 of the first part 165-1 of the recess portion 165 formed in the first portion 161 of the first protective layer 160 exceeds 90% of the width W1 of the first pad 120P1 of the first circuit pattern layer 120, the width of the first part 165-1 of the recess portion 165 may be larger than the width of the first pad 120P1 due to process deviation in the process of forming the first part 165-1 of the recess portion 165, and accordingly, a reliability problem may occur as the side surface of the first pad 120P1 is unintentionally not covered by the protective layer 160.

Meanwhile, the thickness of the first portion 161 of the first protective layer 160 is greater than the thickness of the first pad 120P1 of the first circuit pattern layer 120. For example, the upper surface of the first portion of the first protective layer 160 may be positioned higher than the upper surface of the first pad 120P1 of the first circuit pattern layer 120.

For example, the thickness of the first portion 161 of the first protective layer 160 may range from 105% to 180% of the thickness of the first pad 120P1 of the first circuit pattern layer 120. For example, the thickness of the first portion 161 of the first protective layer 160 may range from 110% to 170% of the thickness of the first pad 120P1 of the first circuit pattern layer 120. For example, the thickness of the first portion 161 of the first protective layer 160 may range from 115% to 165% of the thickness of the first pad 120P1 of the first circuit pattern layer 120. The thickness of the first portion 161 of the first protective layer 160 may refer to a vertical distance between the lower surface and the upper surface of the first portion 161 of the first protective layer 160. For example, the thickness of the first portion 161 of the first protective layer 160 may refer to a vertical distance between the upper surface of the first insulating layer 111 and the upper surface of the first portion 161 of the first protective layer 160. For example, the thickness of the first portion 161 of the first protective layer 160 may mean a vertical distance from the lower surface of the first circuit pattern layer 120 to the upper surface of the first portion 161 of the first protective layer 160. In addition, the thickness of the first circuit pattern layer 120 may refer to the vertical distance from the lower surface to the upper surface of the first circuit pattern layer 120.

If the thickness of the first portion 161 of the first protective layer 160 is less than 105% of the thickness of the first pad 120P1 of the first circuit pattern layer 120, a problem may occur in which the edge region of the upper surface of the first pad 120P1 is not stably protected through the first portion 161 of the first protective layer 160.

In addition, if the thickness of the first portion 161 of the first protective layer 160 exceeds 180% of the thickness of the first pad 120P1 of the first circuit pattern layer 120, an overall thickness of the first protective layer 160 may increase corresponding to the thickness of the first portion 161 of the first protective layer 160, and thus the overall thickness of the circuit board may increase.

Accordingly, the thickness of the first portion 161 of the first protective layer 160 is set to range from 105% to 180% of the thickness of the first pad 120P1 of the first circuit pattern layer 120.

Meanwhile, the first portion 161 of the first protective layer 160 may be divided into a plurality of unit parts. For example, the first portion 161 of the first protective layer 160 may be divided into a first-first portion disposed on the first insulating layer 111 and covering a side surface of the first circuit pattern layer 120, and a first-second portion disposed on the first-first portion and including a first part 165-1 of the recess portion 165.

Also, at least a portion of the first-second portion may be disposed on the first pad 120P1 of the first circuit pattern layer 120. Meanwhile, the first circuit pattern layer 120 may penetrate the first-first portion of the first protective layer 160. For example, the first-first portion of the first protective layer 160 may include a recess portion (not shown) corresponding to a through hole through which the first circuit pattern layer 120 passes.

As described above, the first part 165-1 of the recess portion 165 of the first portion 161 of the first protective layer 160 has a width W2 smaller than the width W1 of the first pad 120P1. Accordingly, the first portion 161 of the first protective layer 160 may cover at least a portion of the upper surface of the first pad 120P1 of the first circuit pattern layer 120. For example, the first portion 161 of the first protective layer 160 may cover an edge region of the upper surface of the first pad 120P1 of the first circuit pattern layer 120, but is not limited thereto. Accordingly, the first portion 161 of the first protective layer 160 may include an overlapping region that vertically overlaps the first pad 120P1 of the first circuit pattern layer 120, and a non-overlapping region that does not vertically overlap the first pad 120P1 of the first circuit pattern layer 120.

Meanwhile, as described above, the first circuit pattern layer 120 includes a trace 120T in addition to the first pad 120P1 and the second pad 120P2. Also, the thickness of the first portion 161 of the first protective layer 160 is greater than the thickness of the first circuit pattern layer 120. Accordingly, the trace 120T of the first circuit pattern layer 120 may be covered with the first portion 161 of the first protective layer 160 disposed on the upper surface of the first insulating layer 111.

The first protective layer 160 includes a second portion 162 disposed on the first portion 161.

The recess portion 165 of the embodiment may include a second part 165-2 formed in the second portion 162 of the first protective layer 160. The second part 165-2 of the recess portion 165 may be connected to the first part 165-1. Through this, in the embodiment, a recess portion 165 having a step may be formed by combining a first part 165-1 formed in the first portion 161 of the first protective layer 160 and a second part 165-2 formed in the second portion 162 of the second protective layer 170.

Specifically, the second part 165-2 of the recess portion 165 formed in the second portion 162 of the first protective layer 160 may vertically overlap the first pad 120P1 of the first circuit pattern layer 120. In addition, the second part 165-2 of the recess portion 165 formed in the second portion 162 of the first protective layer 160 may vertically overlap the first part 165-1 of the recess portion 165 formed in the first portion 161.

At this time, the width W3 of the second recess portion 1620 of the second portion 162 of the first protective layer 160 may be larger than the width W2 of the first part 165-1 of the recess portion 165 formed in the first portion 161 of the first protective layer 160. In addition, the width W2 of the second part 165-2 of the recess portion 165 formed in the second portion 162 of the first protective layer 160 may be larger or smaller than the width W1 of the first pad 120P1 of the first circuit pattern layer 120. That is, the width W3 of the second part 165-2 of the recess portion 165 formed in the second portion 162 of the first protective layer 160 in the embodiment is determined by the width W2 of the first part 165-1 of the recess portion 165 formed in the first portion 161.

Preferably, in order for the recess portion 165 of the first protective layer 160 to have a stepped structure, the embodiment allows for the width of the second part 165-2 of the recess portion 165 formed in the second portion 162 of the first protective layer 160 to be greater than the width of the first part 165-1 of the recess portion 165 formed in the first portion 161 of the first protective layer 160.

However, the embodiment allows the width W3 of the second part 165-2 of the recess portion 165 formed in the second portion 162 of the first protective layer 160 to be increased to the maximum within a possible range, and allows to further improve the reliability of the metal contact layer (IMC).

For example, in order to improve the reliability of the metal contact layer (IMC), this can be achieved by increasing the distance between the upper surface of the first protective layer 160 and the first surface treatment layer 180. In addition, this can be achieved by increasing the thickness of the first protective layer 160. However, when the thickness of the first protective layer 160 increases, the thickness of the circuit board increases accordingly, and the overall thickness of the semiconductor package and/or electronic device accordingly increases.

Accordingly, the embodiment allows the length of the inner wall of the recess portion 165 between the upper surface of the first protective layer 160 and the metal contact layer (IMC) to be increased without increasing the thickness of the first protective layer 160.

Accordingly, the width W3 of the second part 165-2 of the recess portion 165 formed in the second portion 162 of the first protective layer 160 may be larger than the width W1 of the first pad 120P1 of the first circuit pattern layer 120.

For example, the width W3 of the second part 165-2 of the recess portion 165 in the embodiment may range from 102% to 130% of the width W1 of the first pad 120P1. For example, the width W3 of the second part 165-2 of the recess portion 165 may range from 105% to 130% of the width W1 of the first pad 120P1. For example, the width W3 of the second part 165-2 of the recess portion 165 may range from 102% to 130% of the width W1 of the first pad 120P1. If the width of the second part 165-2 of the recess portion 165 is less than 102% of the width of the first pad 120P1, an effect generated by increasing the distance between the upper surface of the first protective layer 160 and the metal contact layer (IMC) by the recess portion 165 having the step structure may be insignificant. In addition, if the width W3 of the second part 165-2 of the recess portion 165 exceeds 130% of the width W1 of the first pad 120P1, physical reliability problems may occur, or the size of the circuit board in the width or length direction may increase. For example, the solder is disposed in the recess portion 165 to connect a circuit board and a semiconductor device. At this time, the first pad 120P1 may be placed adjacent to the second pad 120P2. Additionally, a recess portion 165 may be formed in a region that vertically overlaps the first pad 120P1 and the second pad 120P2.

At this time, if the width of the second part 165-2 of the recess portion 165 exceeds 130% of the width W1 of the first pad 120P1, a distance between the solder disposed between the first pads 120P1 and the solder disposed on the second pad may become too close, and electrical reliability problems may occur due to mutual interference.

In addition, if he width W3 of the second part 165-2 of the recess portion 165 exceeds 130% of the width W1 of the first pad 120P1, a problem may occur where the solder disposed on the first pad 120P1 and the solder disposed on the second pad 120P2 are connected to each other due to process deviation due to spacing between the first pad 120P1 and the second pad 120P21. Additionally, electrical reliability problems such as circuit shorts may occur.

Accordingly, the recess portion 165 formed in the first protective layer 160 in the first embodiment may have a T-shape. Through this, the embodiment can increase the length of the inner wall of the recess portion 165 formed in the first protective layer 160, and accordingly, the distance between the upper surface of the first protective layer 160 and the metal contact layer (IMC) formed on the first surface treatment layer 180 can be increased.

For example, in the comparative example, the inner wall of the recess portion connecting the upper surface of the protective layer and the metal contact layer (IMC) had a structure without an inflection portion. Accordingly, in the comparative example, the thickness of the protective layer 160 had to be increased in order to increase the distance between the inner wall of the recess portion between the upper surface of the protective layer and the metal contact layer (IMC).

Unlike this, in the embodiment, by forming a step in the recess portion 165, the physical reliability of the metal contact layer (IMC) can be improved without increasing the thickness of the protective layer 160.

For example, the inner wall of the recess portion 165 in the embodiment includes a first inner wall 161W corresponding to the first part 165-1 of the recess portion 165. Additionally, the inner wall of the recess portion 165 includes a second inner wall 162W corresponding to the second part 165-2 of the recess portion 165. Additionally, the inner wall of the recess portion 165 in the embodiment includes a third inner wall 163 connecting the first inner wall 161W and the second inner wall 162W.

At this time, when the thickness of the protective layer, the thickness of the circuit pattern layer, and the thickness of the surface treatment layer of the comparative example are the same as the thickness of the protective layer, the thickness of the circuit pattern layer, and the thickness of the surface treatment layer of the present embodiment, the inner wall of the recess portion between the upper surface of the protective layer in the comparative example and the surface treatment layer includes only the first inner wall 161W and the second inner wall 162W. Unlike this, the embodiment allows a third inner wall 163 to be additionally formed between the first inner wall 161W and the second inner wall 162W by giving a step to the recess portion 165, and accordingly, the distance between the upper surface of the first protective layer 160 and the metal contact layer (IMC) can be increased by the length (or width) of the third inner wall 163.

Through this, the embodiment can increase the distance between the protective layer and the metal contact layer without increasing the thickness of the protective layer and the circuit board, and thereby stably protect the metal contact layer from various factors. Therefore, the embodiment can increase the bonding strength between the solder disposed on the first surface treatment layer 180 and the first circuit pattern layer 120, and thus improve physical reliability.

Meanwhile, in FIG. 4, it is shown that the first surface treatment layer 180 is not disposed on the first pad 120P1. However, this is only omitted for the sake of explanation of the recess portion 165 formed in the first protective layer 160, and the first surface treatment layer 180 may also be disposed on the first pad 120P1.

Additionally, in an embodiment, the first surface treatment layer 180 is formed to fill only a portion of the first part 165-1 of the recess portion 165. For example, the step portion of the recess portion 165 in the embodiment may be between the first part 165-1 and the second part 165-2. For example, the step portion may correspond to the third inner wall 163. Additionally, the embodiment allows the upper surface of the first surface treatment layer 180 to be positioned lower than the third inner wall 163. For example, the embodiment allows the upper surface of the first surface treatment layer 180 to be positioned lower than the top of the first inner wall 161W. At this time, when the first surface treatment layer 180 is located higher than the third inner wall 163, the third inner wall 163 will be filled with the first surface treatment layer 180. Accordingly, even if the recess portion 165 has a stepped structure, the distance between the first protective layer 160 and the metal contact layer (IMC) may not increase. Accordingly, the embodiment allows the depth of the first part 165-1 of the recess portion 165 to be greater than the thickness of the first surface treatment layer 180, and allows to increase the distance between the upper surface of the first protective layer 160 and the metal contact layer (IMC).

Meanwhile, in an embodiment, spacing D2 between neighboring recess portions 165 may be smaller than spacing D1 between a plurality of neighboring pads.

For example, the first circuit pattern layer 120 includes a first pad 120P1 and a second pad 120P2 that are adjacent to each other. Additionally, the recess portion 165 may include a first recess portion disposed on the first pad 120P1 and a second recess portion disposed on the second pad 120P2.

At this time, the spacing D1 between the neighboring first pad 120P1 and second pad 120P2 may be larger than the spacing D2 between the second parts between the first recess portion and the second recess portion.

Here, the pitch between the solders SB disposed in the first recess portion and the second recess portion corresponds to the pitch between the first pad 120P1 and the second pad 120P2. For example, the width W3 of the second part 165-2 of the recess portion 165 in the first embodiment may increase compared to the comparative example within a range that does not affect the pitch between the first pad 120P1 and the second pad 120P2 of the first circuit pattern layer 120. Through this, in the embodiment, a bonding area between the solder SB and the first protective layer 160 and the first surface treatment layer 180 can be increased within a range that does not increase the size of the circuit board in the horizontal direction by using the recess portion with the above step, and accordingly, the bonding strength with the solder can be improved. For example, the embodiment provides a second part 165-2 of the recess portion 165 having a width greater than the width of the first pad 120P1, and as a result the amount of solder SB disposed in the recess portion 165 can be increased. Therefore, the bonding force between the solder SB and the first surface treatment layer 180 and the bonding force between the solder SB and the first protective layer 160 can be increased.

Meanwhile, although it has been described above that the width of the second part 165-2 of the recess portion 165 of the present application is larger than the width of the first circuit pattern layer 120, but the embodiment is not limited thereto.

For example, as shown in FIG. 6, the first circuit pattern layer 120 may include a third pad 120-1.

Also, the second part 165-2 of the recess portion 165 may be smaller than the width of the third pad 120-1. For example, the second part 165-2 of the recess portion 165 may vertically overlap a portion of the upper surface of the third pad 120-1.

Accordingly, the third pad 120-1 may include an overlapping region that vertically overlaps the second part 165-2 of the recess portion 165 and a non-overlapping region excluding the overlapping region.

In addition, although the solder SB is shown above as having a width corresponding to the recess portion 165, but the embodiment is not limited thereto. For example, in FIGS. 5 and 6, the solder SB has a structure in which it does not contact the upper surface of the protective layer 160.

Unlike this, as in FIG. 7, a reflow process is performed while the solder SB1 is disposed in the recess portion 165 of the protective layer 160. In the reflow process, at least a portion of the solder SB1 may be expanded into a region that vertically overlaps the upper surface of the protective layer 160 (for example, a region that does not vertically overlap the second part of the recess portion). Accordingly, at least a portion of the solder SB1 may include an expanded region that extends from the second part 165-2 of the recess portion 165 and is disposed on the upper surface of the protective layer 160.

Meanwhile, the first part 165-1 and the second part of the recess portion 165 of the first protective layer 160 in FIG. 4 each had a rectangular vertical cross-sectional shape. For example, the vertical cross-sectional shape of each of the first part 165-1 and the second part 165-2 of the recess portion 165 may have a square shape.

For example, the first part 165-1 and the second part 165-2 of the recess portion 165 in FIG. 4 may each have a cylindrical shape with the same upper and lower widths.

At this time, the first part 165-1 and the second part 165-2 of the recess portion 165 formed in the first protective layer 160 are formed through a process of exposing and developing the first protective layer 160.

Accordingly, the embodiment can adjust the exposure and development conditions. Therefore, as shown in FIG. 8, the vertical cross-sectional shapes of the first part 165-1a and the second part 165-2a of the recess portion 165a may have a trapezoidal shape with different upper and lower widths.

For example, the first inner wall 161W of the first part 165-1a of the recess portion 165a may have an inclination in which the width gradually decreases from the upper surface of the first portion 161 of the first protective layer 160 toward the first pad 120P1.

In addition, the second inner wall 162W of the second part 165-2a of the recess portion 165a may have an inclination in which the width gradually decreases from the upper surface of the second portion 162 of the first protective layer 160 toward the first part 165-1a of the recess portion 165a.

At this time, the inclination of the first inner wall 161W of the first part 165-1a may be the same as the inclination of the second inner wall 162W of the second part 165-2a, or may be different.

Accordingly, the embodiment allows the first inner wall 161W and the second inner wall 162W to have an inclination, thereby further increasing the length of the inner wall of the recess portion 165a. Accordingly, the embodiment can further improve the physical reliability of the metal contact layer (IMC).

Below, a second embodiment of the present application will be described. At this time, an overall structure of the circuit board of the second embodiment is same as that of the circuit board of the first embodiment shown in FIG. 4. Specifically, the circuit board of the second embodiment has a difference in the width of the recess portion of the first protective layer disposed on an uppermost side of the circuit board compared to the circuit board of the first embodiment.

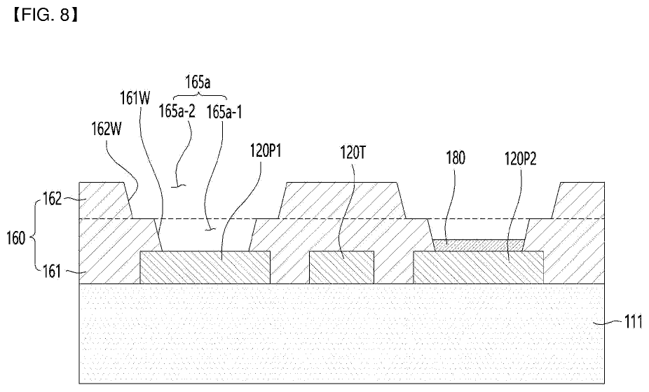

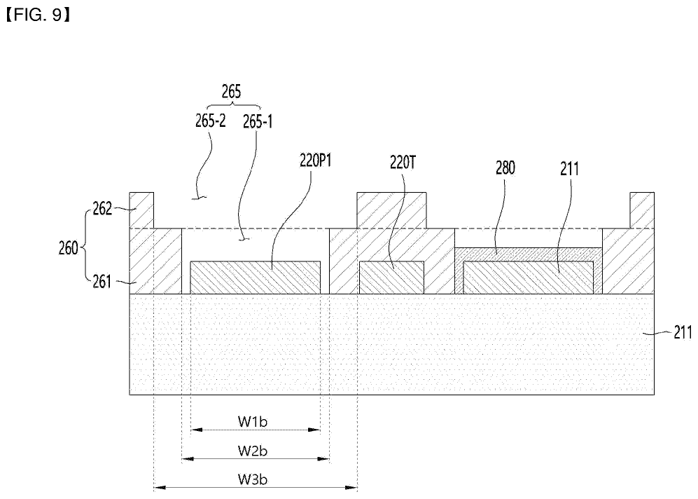

FIG. 9 is a diagram showing a circuit board according to a second embodiment.

Referring to FIG. 9, the circuit board of the second embodiment includes a first insulating layer 211. The first insulating layer 211 is substantially the same as the first insulating layer 111 of FIG. 4, and therefore detailed description thereof will be omitted.

Additionally, the circuit board of the second embodiment includes a first circuit pattern layer disposed on the upper surface of the first insulating layer 211. The first circuit pattern layer may include a first pad 220P1, a second pad 220P2, and a trace 220T.

Meanwhile, the circuit board of the second embodiment includes a first protective layer 260 disposed on an upper surface of the first insulating layer 211.

The first protective layer 260 may include a recess portion 265 disposed on the upper surface of the first insulating layer 211 and vertically overlapping with the first pad 220P1 of the first circuit pattern layer.

Specifically, the first protective layer 160 includes a first portion 261 including the first part 265-1 of the recess portion 265. In addition, the first protective layer 260 may include a second portion 262 disposed on the first portion 261 and including a second part 265-2 of the recess portion 265 that vertically overlaps the first pad 220P1.

The first portion 261 of the first protective layer 260 includes a first part 265-1 of the recess portion 265 having a width W2b greater than the width W1b of the first pad 220P1. Accordingly, the first part 265-1 of the recess portion 265 formed in the first portion 261 of the first protective layer 260 includes an overlapping region that vertically overlaps the first pad 220P1, and a non-overlapping region that does not vertically overlap the first pad 220P1. And, at least a portion of the upper surface of the first insulating layer 211 may include an exposed region that does not vertically overlap the first pad 220P1 and the first protective layer 260 but vertically overlaps the recess portion 265.

At this time, the width W1b of the first pad 220P1 in the second embodiment may be smaller than the width W1 of the first pad 120P1 in the first embodiment. Also, the width W2b of the first part 265-1 of the recess portion 265 in the second embodiment may correspond to the width W1 of the first pad 120P1 in the first embodiment.

Meanwhile, the first protective layer 260 includes a second portion 262 including the second part 265-2 of the recess portion 265. The width W3b of the second part 265-2 of the recess portion 265 of the second portion 262 may be larger than the width W1b of the first pad 220P1 and the width W2b of the first part 265-1 of the recess portion 265. For example, the width W3b of the second part 265-2 of the recess portion 265 may correspond to the width W3 of the second part 165-2 of the recess portion 165 in the first embodiment, but is not limited thereto.

Additionally, the first surface treatment layer 280 in the second embodiment may fill a portion of the first part 265-1 of the recess portion 265. At this time, the first surface treatment layer 280 in the second embodiment may include a first region in contact with the upper surface of the first pad 220P1, and a second region in contact with the side surface of the first pad 220P1 and a portion of the inner wall of the first part 265-1 of the recess portion 265.

At this time, a width corresponding to the horizontal distance from a leftmost end to a rightmost end of the first surface treatment layer 280 may correspond to the width of the first pad 220P1 described in the first embodiment. Accordingly, the second embodiment can improve the physical reliability of the metal contact layer (IMC) according to bonding with the solder disposed on the first surface treatment layer 280 without increasing the width of the first pad 220P1.

Meanwhile, in FIG. 9, the inner wall of the first part 265-1 and the inner wall of the second part 265-2 of the recess portion 265 are shown as having a right angle to a main surface, but the present invention is not limited thereto. For example, the inner wall of the first part 265-1 and the inner wall of the second part 265-2 of the recess portion 265 may be inclined with respect to the main surface.

As described above, in the circuit board according to the second embodiment, the recess portion of the first protective layer can be formed as an NSMD type. Accordingly, the embodiment allows the NSMD type recess portion to have a stepped structure including a first part and a second part. According to the second embodiment, in addition to the effects of the first embodiment, and the design freedom of the first circuit pattern layer can be further improved, and thus product satisfaction can be improved.

Meanwhile, when solder is disposed in the recess portion 265, the solder may have a width corresponding to the recess portion 265, or alternatively, as described above, the solder may include an expanded region that extends outward from the recess portion 265 and contacts the upper surface of the protective layer 260.

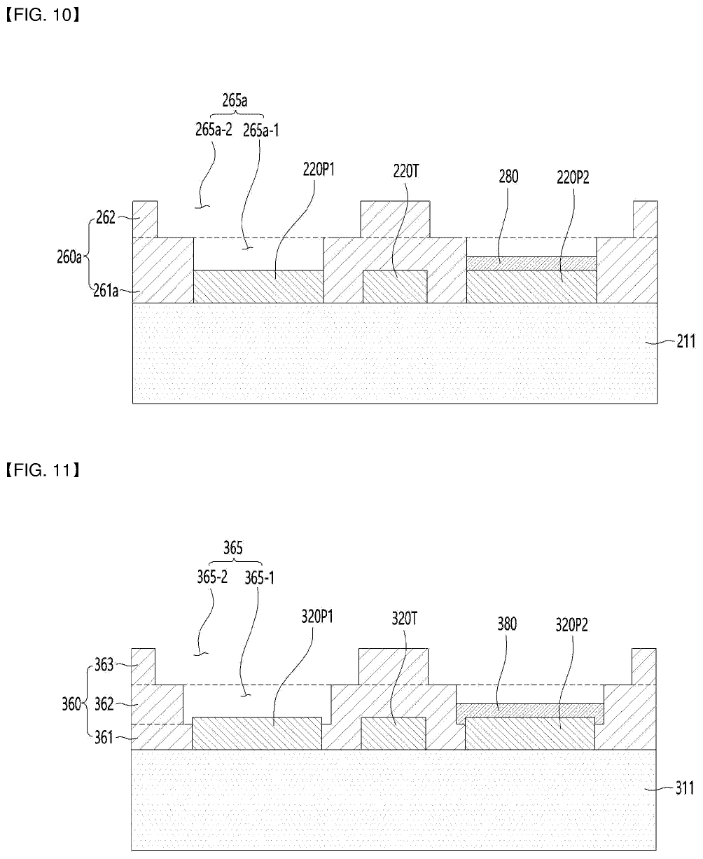

FIG. 10 is a diagram showing a circuit board according to a third embodiment.

Referring to FIG. 10, the circuit board according to the third embodiment has the same basic structure as the circuit board of the second embodiment of FIG. 9, and there is a difference in the width of the first part of the recess portion formed in the first portion of the first protective layer and the surface treatment layer disposed in the first part of the recess portion.

For example, the first protective layer 260a may include a first portion 261a including the first part 265-1a of the recess portion 265a.

And, the first surface treatment layer 280 may be disposed in the first part 265-1a of the recess portion 265a.

At this time, the first part 265-1a of the recess portion 265a formed in the first portion 261a of the first protective layer 260 may have a width W1b that is the same as the width of the first pad 220P1a. Accordingly, the side surface of the first pad 220P1a may be covered with the first portion 261a of the first protective layer 260. Accordingly, the width of the first surface treatment layer 280 may be the same as the width of the first pad 220P1a.

FIG. 11 is a diagram showing a circuit board according to a fourth embodiment.

Referring to FIG. 11, the circuit board according to the fourth embodiment has a difference in the depth of the first part of the recess portion compared to the circuit board according to the second embodiment.

For example, in the second embodiment, a depth of the first part 265-1 of the recess portion 265 corresponded to a thickness of the first portion 261 of the first protective layer 260.

Alternatively, a depth of the first part of the recess portion in the fourth embodiment may have a depth smaller than the thickness of the first portion of the first protective layer 260.

Accordingly, in the second embodiment, an entire side surface of the first pad of the first circuit pattern layer is horizontally overlapped the first part 265-1 of the recess portion 265.

Differently, in the fourth embodiment, a part of the side surface of the first pad may be covered with the first protective layer, and a remaining part may overlap horizontally with the first part of the recess portion.

For example, the first protective layer 360 includes a first portion 361 and 362 and a second portion 363 disposed on the first portion 361 and 362.

The first part 365-1 of the protective layer 360 having a width greater than the width of the first pad 320P1 of the first circuit pattern layer is formed in the first portion 361 and 360 of the first protective layer 360.

At this time, the first part 365-1 of the recess portion 365 may be formed by opening a portion of the first portion 361 and 362 of the first protective layer 360.

Accordingly, the first portions 361 and 362 may be divided into a region including the first part 365-1 and a region in which the first part 365-1 is not formed.

For example, the first portions 361 and 362 may include a first-first portion 361 disposed on the first insulating layer 311. The first-first portion 361 may be formed to surround the side surface of the first pad 320P1. For example, the first-first portion 361 may be formed to cover a portion of the side surface of the first pad 320P1. At this time, the upper surface of the first-first portion 361 may be located lower than the upper surface of the first pad 320P1. Accordingly, the side surface of the first pad 320P1 may include a first side surface that overlaps the first-first portion 361 in the horizontal direction and a second side surface other than the first side surface. Also, the first side surface of the first pad 320P1 may be covered with the first-first portion 361. At this time, the first-first portion 361 of the first protective layer 360 may include a through hole (not shown) through which the first pad 320P1 passes. At this time, the through hole of the first-first portion 361 may also be expressed as a recess portion. The through hole of the first-first portion 361 may have a width equal to that of the first pad 320P1. Accordingly, the first-first portion 361 may be formed to surround the first side surface of the first pad 320P1.

The first portions 361 and 362 of the first protective layer 360 include a first-second portion 362 disposed on the first-first portion 361. And, the first-second portion 362 includes the first part 365-1 of the recess portion 365. For example, the first-second portion 362 includes a first part 365-1 of the recess portion 365 having a width greater than the width of the pad 320P1. A lower surface of the first-second portion 362 may be located lower than the upper surface of the first pad 320P1. For example, the lower surface of the first part 365-1 of the recess portion 365 formed in the first-second portion 362 may be positioned lower than the upper surface of the first pad 320P1. Accordingly, the second side surface of the first pad 320P1 may overlap the first part 365-1 of the recess portion 365 of the first-second portion 362 in the horizontal direction. Accordingly, the second side surface of the first pad 320P1 may be spaced apart from the inner wall of the first part 365-1 of the recess portion 365 formed in the first-second portion 362 by a certain spacing.

The second portion 363 of the first protective layer 360 is disposed on the first-second portion 362 of the first protective layer 360. The second portion 363 includes a second part 365-2 having a width greater than a width of the first part 365-1 of the recess portion 365.

As above, according to the fourth embodiment, the first part 365-1 of the recess portion 365 is formed to penetrate only a portion (first-second portion 362) rather than the entire first portion 361 and 362 of the first protective layer 360. Accordingly, the first side surface, which is part of the side surface of the first pad 320P1, is covered with the first-first portion 361. In addition, the second side surface, which is the remaining part, may be spaced apart from the first protective layer as it horizontally overlaps the recess portion 365 of the first-second portion 362.

The first surface treatment layer 380 may fill a portion of the first part 365-1 of the recess portion 365 formed in the first protective layer 360.

At this time, the first surface treatment layer 380 in the second embodiment was formed to surround the entire side surface of the first pad.

Unlike this, the first surface treatment layer 380 in the fourth embodiment may be disposed to surround only the second side surface of the first pad 320P1.

In the circuit boards of the first to fourth embodiments described above, the first protective layer includes a recess portion having various types of step structures, and a surface treatment layer is disposed within the recess portion of the step structure. At this time, the uppermost end of the surface treatment layer in the embodiment is located lower than the step portion of the recess portion. Through this, the embodiment can increase the distance between the metal contact layer (IMC) formed as the solder is disposed on the surface treatment layer and the upper surface of the first protective layer, and this can improve the physical reliability of the metal contact layer (IMC).

Meanwhile, only the structure of the recess portion formed in the first protective layer has been described in FIGS. 4 to 11. The recess portion formed in the second protective layer may also have substantially the same structure as the recess portion formed in the first protective layer.

The circuit board in the embodiment comprises a protective layer disposed on an outermost layer and having a recess portion that vertically overlaps the pad. At this time, the recess portion formed in the protective layer may have a step. For example, the recess portion formed in the protective layer includes a first part of the recess portion adjacent to the pad and having a first width, and a second part formed on the first part and having a width greater than that of the first part. Accordingly, the embodiment increases a length of an inner wall of the protective layer, thereby increasing a length of an inner wall of the recess portion between an upper surface of the protective layer and the pad. Meanwhile, a surface treatment layer is disposed on the pad, and a solder is disposed on the surface treatment layer. At this time, a metal contact layer is formed between the solder and the surface treatment layer as the solder is disposed on the surface treatment layer. At this time, the embodiment allows the recess portion to have a step, and allows to increase the length of the inner wall of the recess portion between the upper surface of the protective layer and the metal bonding layer while increasing a contact area of an upper surface of the solder.

For example, the comparative example had a structure in which an inflection portion was not provided on the inner wall of the recess portion connecting the upper surface of the protective layer and the metal contact layer (IMC). Accordingly, in the comparative example, a thickness of the protective layer had to be increased in order to increase the distance of the inner wall of the recess portion between the upper surface of the protective layer and the metal contact layer (IMC).

Alternatively, the embodiment may form a step in the recess portion to increase the length of the inner wall of the recess portion between the metal contact layer (IMC) and the upper surface of the protective layer without increasing the thickness of the protective layer, and accordingly, the physical reliability of the metal contact layer (IMC) can be improved.

For example, the inner wall of the recess portion in the embodiment includes a first inner wall corresponding to the first part of the recess portion, a second inner wall corresponding to the second part, and a third inner wall between the first inner wall 161W and the second inner wall. At this time, when a thickness of the protective layer, a thickness of the circuit pattern layer, and a thickness of the surface treatment layer in the comparative example is the same as a thickness of the protective layer, a thickness of the circuit pattern layer, and a thickness of the surface treatment layer in the present embodiment, an inner wall of the recess portion between the upper surface of the protective layer in the comparative example and the surface treatment layer only the first inner wall and the second inner wall. Alternatively, the embodiment allows a third inner wall to be additionally formed between the first inner wall and the second inner wall by providing a step in the recess portion, and a distance between the upper surface of the protective layer and the metal contact layer (IMC) may be increased by a length (or width) of the third inner wall.

Through this, the embodiment can increase the distance between the protective layer and the metal contact layer without increasing the thickness of the protective layer and the circuit board, and thereby stably protect the metal contact layer from various factors. Accordingly, the embodiment can increase the bonding strength between the solder disposed on the surface treatment layer and the circuit pattern layer, and thus improve physical reliability.

Additionally, the embodiment allows the width of the second part of the recess portion to be larger than the width of the pad. Accordingly, the embodiment increases the width of the second part of the recess portion to the maximum within a possible range to further improve the reliability of the metal contact layer (IMC).

### Package Substrate

Hereinafter, a package substrate according to an embodiment will be described.

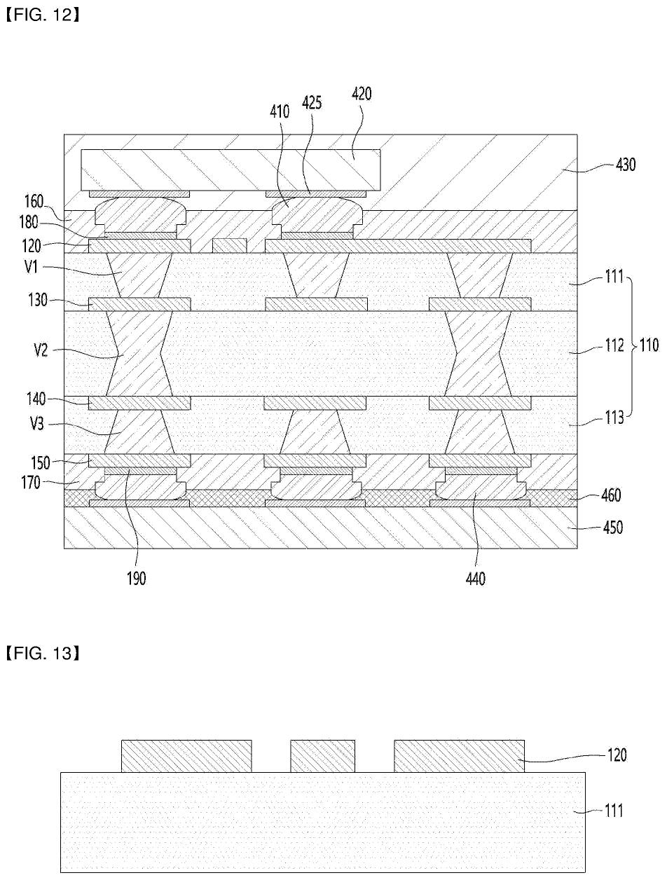

FIG. 12 is a diagram showing a package substrate according to an embodiment.

The package substrate may have a structure in which a semiconductor device is disposed on the first or second substrate shown in any one of FIGS. 2A to 2G.

For example, referring to FIG. 12, the package substrate of the embodiment may have a structure in which at least one semiconductor device is mounted on the circuit board and a main board is coupled to the circuit board. However, the embodiment is not limited thereto, and only semiconductor devices may be mounted on the circuit board, or only the main board may be combined on the circuit board.

The package substrate in the embodiment may include a first connection part 410 formed on the first surface treatment layer 180. The first connection part 410 may have a spherical shape. For example, the cross section of the first connection part 410 may include a circular shape or a semicircular shape. For example, the cross section of the first connection part 410 may include a partially or entirely rounded shape. The cross-sectional shape of the first connection part 410 may be flat on one side surface and curved on the other side surface. The first connection part 410 may be a solder ball.

A semiconductor device 420 may be disposed on the first connection part 410. The semiconductor device 420 may be a processor chip. For example, the chip 420 may be an application processor (AP) chip of any one of a central processor (e.g., CPU), a graphics processor (e.g., GPU), a digital signal processor, a cryptographic processor, a microprocessor, and a microcontroller.

At this time, a terminal 425 may be included on the lower surface of the semiconductor device 420, and the terminal 425 may be electrically connected to the first circuit pattern layer 120 of the circuit board through the first connection part 410.

Meanwhile, the package substrate of the embodiment may allow a plurality of semiconductor devices to be arranged at a certain spacing from each other on one circuit board. For example, the semiconductor device 420 may include a first semiconductor device and a second semiconductor device that are spaced apart from each other.

Also, the first semiconductor device and the second semiconductor device may be different types of application processor (AP) chips.

Meanwhile, the first semiconductor device and the second semiconductor device may be spaced apart from each other at a certain spacing on the circuit board. For example, the spacing between the first semiconductor device and the second semiconductor device may be 150 μm or less. For example, the spacing between the first semiconductor device and the second semiconductor device may be 120 μm or less. For example, the spacing between the first semiconductor device and the second semiconductor device may be 100 μm or less.

Preferably, for example, the spacing between the first semiconductor device and the second semiconductor device may range from 60 μm to 150 μm. For example, the spacing between the first semiconductor device and the second semiconductor device may range from 70 μm to 120 μm. For example, the spacing between the first semiconductor device and the second semiconductor device may range from 80 μm to 110 μm. For example, if the spacing between the first semiconductor device and the second semiconductor device is less than 60 μm, interference between the first semiconductor device and the second semiconductor may cause problems with the operational reliability of the first semiconductor device and/or the second semiconductor device. For example, if the spacing between the first semiconductor element and the second semiconductor element is greater than 150 μm, signal transmission loss may increase as the distance between the first semiconductor device and the second semiconductor device increases.

The package substrate may include a first molding layer 430. The first molding layer 430 may be disposed to cover the semiconductor device 420. For example, the first molding layer 430 may be an epoxy mold compound (EMC) formed to protect the mounted semiconductor device 420, but is not limited thereto.

At this time, the first molding layer 430 may have a low dielectric constant to increase heat dissipation characteristics. For example, the dielectric constant (Dk) of the first molding layer 430 may be 0.2 to 10. For example, the dielectric constant (Dk) of the first molding layer 430 may be 0.5 to 8. For example, the dielectric constant (Dk) of the first molding layer 430 may be 0.8 to 5. Accordingly, in the embodiment, the first molding layer 430 has a low dielectric constant to improve heat dissipation characteristics for heat generated from the semiconductor device 420.

Meanwhile, the package substrate may include a second connection part 440 disposed on the lowermost side of the circuit board. The second connection part 440 may be disposed under the second surface treatment layer that vertically overlaps the recess portion of the second protective layer. Additionally, the package substrate in the embodiment may include a main board 450 of an external device coupled below the second connection part 440. Additionally, a second molding layer 460 may be formed between the main board 450 and the circuit board. The second molding layer 460 may mold components between the main board 450 and the circuit board, including the second connection part 440.

### Manufacturing Method

Hereinafter, a method of manufacturing a circuit board according to an embodiment will be described.

FIGS. 13 to 19 are diagrams showing a method of manufacturing a circuit board according to an embodiment in order of processes. Hereinafter, the description will focus on the manufacturing method of an outermost layer of the circuit board.

Referring to FIG. 13, the embodiment proceeds with a process of disposing a first insulating layer 111 and a process of forming a first circuit pattern layer 120 on the first insulating layer 111. At this time, the first circuit pattern layer 120 may include at least one pad and a trace connected to the pad.

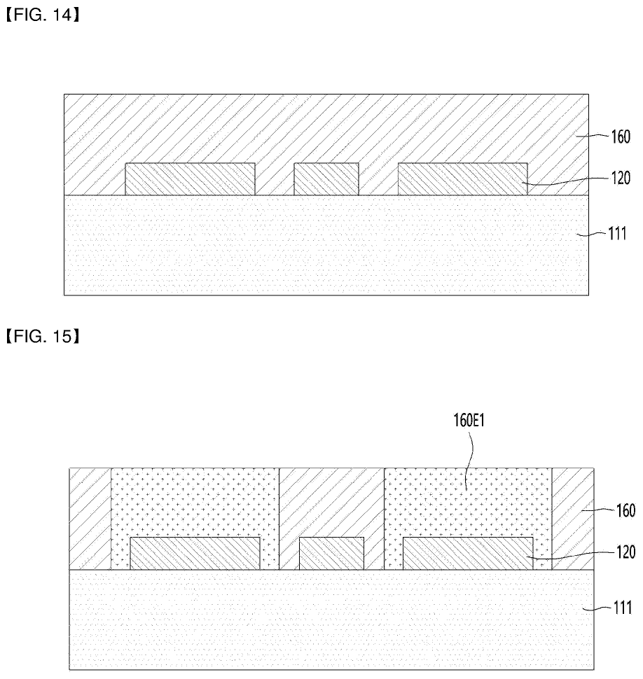

Next, referring to FIG. 14, in the embodiment, a first protective layer 160 is formed on the first insulating layer 111. At this time, the first protective layer 160 may be disposed on the first insulating layer 111 and the first circuit pattern layer 120.

Specifically, the first protective layer 160 may be formed to entirely cover the upper surface of the first insulating layer 111 and the upper surface of the first circuit pattern layer 120. For example, the first protective layer 160 may not include a recess portion.

Next, as shown in FIG. 15, the embodiment may proceed with a process of primary exposing the first protective layer 160 using an exposure mask (not shown). The primary exposure process may be performed based on a region of the entire region of the first protective layer 160 that vertically overlaps the pad of the first circuit pattern layer 120. For example, the primary exposure process may be performed on a region of the entire region of the first protective layer 160 that does not vertically overlap a region where the second part of the recess portion 165 will be formed. Accordingly, exposure may not be performed on the region where the second part 165-2 of the recess portion 165 will be formed through the primary exposure process. Specifically, remaining regions of the entire region of the first protective layer 160 excluding the region 160E1 where the second part 165-2 of the recess portion 165 will be formed may be exposed and cured through the primary exposure process. At this time, a portion that receives light through the primary exposure process (for example, the remaining regions excluding the region 160E1) is cured, and accordingly, thinning is not performed in a subsequent development process.

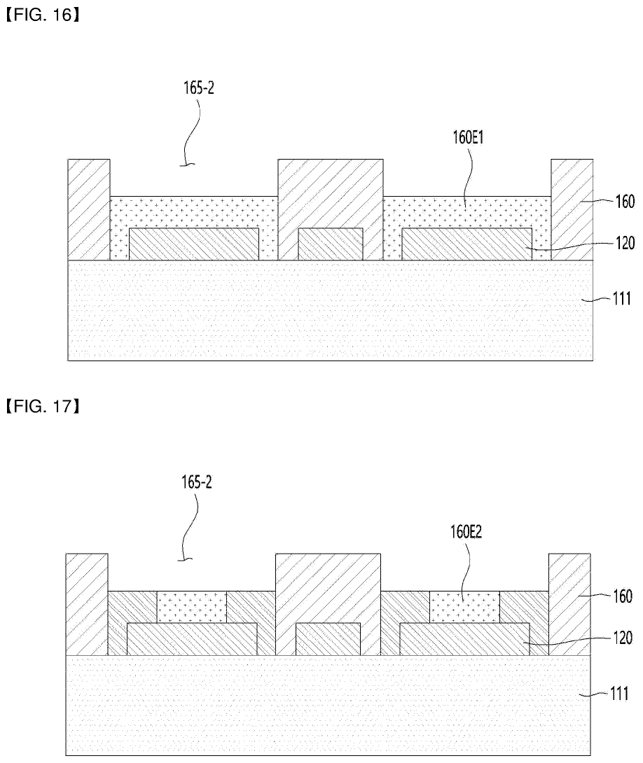

Next, as in FIG. 16, the embodiment may proceed with a process of forming a second part 165-2 of the recess portion 165 that opens the region 160E1 by performing the first development process to develop the region 160E1. The first development process may include a process of thinning the region (160E1) where the exposure and curing have not occurred, using organic alkaline compounds containing tetramethylammonium hydroxide (TMAH) or trimethyl-2-hydroxyethylammonium hydroxide (choline). At this time, the embodiment may adjust the depth of the second part 165-2 of the recess portion 165 by adjusting conditions such as the development process time. For example, the embodiment does not develop the entire region 160E1, but may proceed with the process of forming a second recess portion 1620 that opens a portion of the region 160E1 by adjusting development conditions.

Next, as shown in FIG. 17, the embodiment may proceed with a secondary exposure process. That is, in the primary exposure, the region 160E1 was not exposed and thus thinning occurred in the first development process. And, in the embodiment, a secondary exposure process is performed on the region (160E1). For example, the embodiment may proceed with a process of exposing and developing the remaining regions of the region 160E1 except for the region 160E2 where the first part 165-1 of the recess portion 165 will be formed.

Next, as shown in FIG. 18, the embodiment may proceed with a secondary development process. The secondary development process may include a process of thinning a region 160E2 that has not been exposed or cured in the secondary exposure process using organic alkaline compounds containing tetramethylammonium hydroxide (TMAH) or trimethyl-2-hydroxyethylammonium hydroxide (choline). Accordingly, the first part 165-1 of the recess portion 165, which vertically overlaps the second part 165-2 of the recess portion 165 may be formed on the first insulating layer 111 through a secondary development process. Also, the first part 165-1 of the recess portion 165 has a smaller width than the second part 165-2 of the recess portion 165. Through this, in the embodiment, a recess portion having a step can be formed.

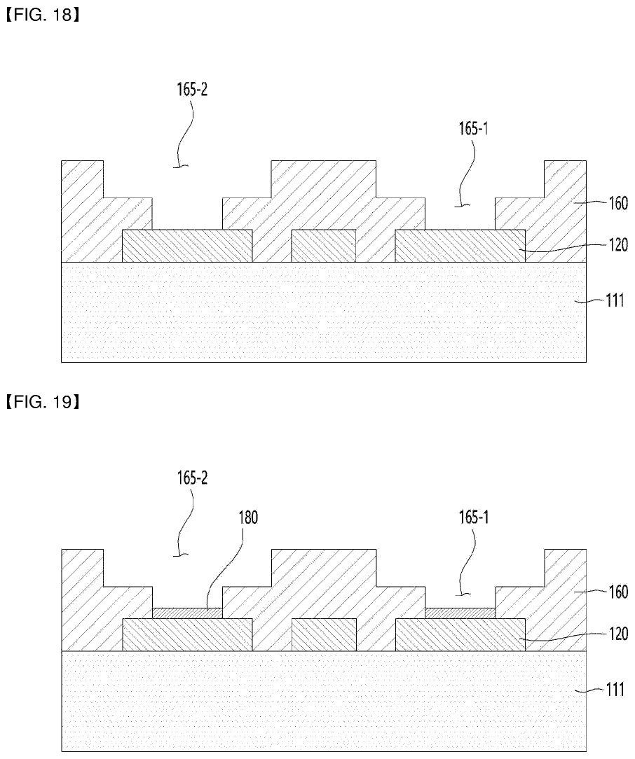

Next, as in FIG. 19, the embodiment may proceed with a process of forming the first surface treatment layer 180 on the first circuit pattern layer vertically overlapping the first part 165-1 of the recess portion 165. At this time, the first surface treatment layer 180 is formed to fill only a portion of the first part 165-1, and thus may have a height lower than the uppermost end of the first part 165-1.

The circuit board in the embodiment comprises a protective layer disposed on an outermost layer and having a recess portion that vertically overlaps the pad. At this time, the recess portion formed in the protective layer may have a step. For example, the recess portion formed in the protective layer includes a first part of the recess portion adjacent to the pad and having a first width, and a second part formed on the first part and having a width greater than that of the first part. Accordingly, the embodiment increases a length of an inner wall of the protective layer, thereby increasing a length of an inner wall of the recess portion between an upper surface of the protective layer and the pad. Meanwhile, a surface treatment layer is disposed on the pad, and a solder is disposed on the surface treatment layer. At this time, a metal contact layer is formed between the solder and the surface treatment layer as the solder is disposed on the surface treatment layer. At this time, the embodiment allows the recess portion to have a step, and allows to increase the length of the inner wall of the recess portion between the upper surface of the protective layer and the metal bonding layer while increasing a contact area of an upper surface of the solder.

For example, the comparative example had a structure in which an inflection portion was not provided on the inner wall of the recess portion connecting the upper surface of the protective layer and the metal contact layer (IMC). Accordingly, in the comparative example, a thickness of the protective layer had to be increased in order to increase the distance of the inner wall of the recess portion between the upper surface of the protective layer and the metal contact layer (IMC).

Alternatively, the embodiment may form a step in the recess portion to increase the length of the inner wall of the recess portion between the metal contact layer (IMC) and the upper surface of the protective layer without increasing the thickness of the protective layer, and accordingly, the physical reliability of the metal contact layer (IMC) can be improved.

For example, the inner wall of the recess portion in the embodiment includes a first inner wall corresponding to the first part of the recess portion, a second inner wall corresponding to the second part, and a third inner wall between the first inner wall 161W and the second inner wall. At this time, when a thickness of the protective layer, a thickness of the circuit pattern layer, and a thickness of the surface treatment layer in the comparative example is the same as a thickness of the protective layer, a thickness of the circuit pattern layer, and a thickness of the surface treatment layer in the present embodiment, an inner wall of the recess portion between the upper surface of the protective layer in the comparative example and the surface treatment layer only the first inner wall and the second inner wall. Alternatively, the embodiment allows a third inner wall to be additionally formed between the first inner wall and the second inner wall by providing a step in the recess portion, and a distance between the upper surface of the protective layer and the metal contact layer (IMC) may be increased by a length (or width) of the third inner wall.

Through this, the embodiment can increase the distance between the protective layer and the metal contact layer without increasing the thickness of the protective layer and the circuit board, and thereby stably protect the metal contact layer from various factors. Accordingly, the embodiment can increase the bonding strength between the solder disposed on the surface treatment layer and the circuit pattern layer, and thus improve physical reliability.

Additionally, the embodiment allows the width of the second part of the recess portion to be larger than the width of the pad. Accordingly, the embodiment increases the width of the second part of the recess portion to the maximum within a possible range to further improve the reliability of the metal contact layer (IMC).

On the other hand, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other. Furthermore, when the circuit board having the above-described characteristics of the invention is used in a transportation device such as a vehicle, it is possible to transmit a high-current signal required by the vehicle at a high speed, thereby improving the safety of the transportation device. Furthermore, the circuit board and the semiconductor package including the same can be operated normally even in an unexpected situation occurring in various driving environments of the transportation device, thereby safely protecting the driver.

The features, structures, effects, etc. described in the embodiments above are included in at least one embodiment of the present invention and are not necessarily limited to only one embodiment. Furthermore, the features, structures, effects, etc. illustrated in each embodiment may be combined or modified and implemented in other embodiments by a person with ordinary knowledge in the field to which the embodiments belong. Therefore, contents related to such combinations and modifications should be construed as being included in the scope of the present invention.

In addition, although the above description focuses on examples, this is only an example and does not limit the present invention, those of ordinary skill in the field to which the present invention pertains will recognize that various modifications and applications not exemplified above are possible without departing from the essential characteristics of the present embodiment. For example, each component specifically shown in the examples may be modified and implemented. And these variations and differences in application should be construed as being included in the scope of the present invention as defined in the appended claims.

1. A circuit board comprising:
an insulating layer;
a pad disposed on the insulating layer; and
a protective layer disposed on the insulating layer and including a recess portion vertically overlapping with the pad,
wherein the protective layer includes:
a first portion including a first part of the recess portion; and
a second portion disposed on the first portion and including a second part of the recess portion connected to the first portion, and
wherein a width of the second part of the recess portion is greater than a width of the first part of the recess portion.

2. The circuit board of claim 1, wherein the recess portion includes at least one point among a point where a width changes, a point where an inclination of an inner wall changes, and a point where a curvature of the inner wall changes, and
wherein the first part and the second part of the recess portion are divided based on the point.

3. The circuit board of claim 2, further comprising:
a surface treatment layer disposed in the first part of the recess portion.

4. The circuit board of claim 3, wherein an upper surface of the surface treatment layer is located lower than an upper surface of the first portion of the protective layer.

5. The circuit board of claim 3, further comprising:
a solder disposed on the surface treatment layer and disposed in the first part and the second part of the recess portion.

6. The circuit board of claim 1, wherein the first part of the recess portion has a width smaller than a width of the pad.

7. The circuit board of claim 6, wherein the second part of the recess portion has a width greater than the width of the pad.

8. The circuit board of claim 1, wherein the pad includes a first pad and a second pad disposed adjacent to each other on the insulating layer,
wherein the recess portion includes:
a first recess portion vertically overlapping the first pad, and
a second recess portion vertically overlapping the second pad,
wherein a spacing between the second part of the first recess portion and the second part of the second recess portion is smaller than a spacing between the first pad and the second pad.

9. The circuit board of claim 3, wherein the first part of the recess portion has a width greater than a width of the pad,
wherein at least a portion of a side surface of the pad is spaced apart from the first portion of the protective layer, and
wherein the surface treatment layer includes a region in contact with the side surface of the pad.

10. The circuit board of claim 9, wherein a lower surface of the first part of the recess portion is located higher than a lower surface of the pad,
wherein the side surface of the pad includes a first side surface covered by the first portion of the protective layer and a second side surface covered with the surface treatment layer.

11. The circuit board of claim 3, wherein the first part of the recess portion has a width equal to the width of the pad, and
wherein the surface treatment layer has a width equal to the width of the pad and is disposed in the first part of the recess portion.

12. The circuit board of claim 1, wherein at least one of the first part and the second part of the recess portion has an inclination whose width gradually decreases toward the pad.

13. A circuit board comprising:
a first outermost insulating layer;
a first outermost circuit pattern layer disposed on the first outermost insulating layer and including a first pad;
a first protective layer disposed on the first outermost insulating layer and including a first recess portion vertically overlapping the first pad;
a second outermost insulating layer disposed under the first outermost insulating layer;
a second outermost circuit pattern layer disposed under the second outermost insulating layer and including a second pad; and
a second protective layer disposed under the second outermost insulating layer and including a second recess portion vertically overlapping the second pad,
wherein the first recess portion includes:
a first-first part having a width smaller than a width of the first pad and formed on the first pad; and
a first-second part formed on the first-first part and having a width greater than a width of each of the first pad and the first-first part, and
wherein the second recess portion includes:
a second-first part formed under the second pad and having a width less than a width of the second pad; and
a second-second part formed on the second-first part and having a width greater than the width of each of the second pad and the second-first part.

14. The circuit board of claim 13, further comprising:
a first surface treatment layer disposed in the first-first part of the first recess portion and having an upper surface lower than an uppermost end of an inner wall of the first-first part; and
a second surface treatment layer disposed in the second-first part of the second recess portion and having a lower surface higher than a lowermost end of an inner wall of the second-first part.

15. A package substrate comprising:
a first outermost insulating layer;
a first outermost circuit pattern layer disposed on the first outermost insulating layer and including a first pad;
a first protective layer disposed on the first outermost insulating layer and including a first recess portion that vertically overlaps the first pad and has a first step;
a second outermost insulating layer disposed under the first outermost insulating layer;
a second outermost circuit pattern layer disposed under the second outermost insulating layer and including a second pad; and
a second protective layer disposed under the second outermost insulating layer and including a second recess portion that vertically overlaps the second pad and has a second step;
a first surface treatment layer disposed in the first recess portion of the first protective layer and having an upper surface positioned lower than the first step;
a first connection part disposed on the first surface treatment layer to fill the first recess portion;
a second surface treatment layer disposed in the second recess portion of the second protective layer and having a lower surface positioned higher than the second step;
a second connection part disposed under the second surface treatment layer and filling the second recess portion;
a chip mounted on the first connection part; and
an external board attached under the second connection part.

16. The package substrate of claim 15, further comprising:
a first metal contact layer disposed between an upper surface of the first surface treatment layer and the first connection part; and
a second metal contact layer disposed between a lower surface of the second surface treatment layer and the second connection part,
wherein an upper surface of the first metal contact layer is located lower than the first step, and a lower surface of the second metal contact layer is positioned higher than the second step.
